(19) United States
(12) Patent Application Publication
(10) Pub. No.: US 2011/0031988 A1
(43) Pub. Date: Feb. 10, 2011

(54) REDUCING SIGNAL DISTORTIONS

(76) Inventors: Lindy Jane Murphy, Surbiton (GB); Hugh Allen Oliver Hill, (US)

Correspondence Address: ROCHE DIAGNOSTICS OPERATIONS INC., 9115 Hague Road, Indianapolis, IN, 46250-0457, US

(21) Appl. No.: 12/697,712

(22) Filed: Feb. 1, 2010

Related U.S. Application Data
(63) Continuation of application No. PCT/GB2008/002653, filed on Aug. 4, 2008.

(30) Foreign Application Priority Data
Aug. 2, 2007 (GB) 0715036.0

(51) Int. Cl. G01R 27/08

(52) U.S. Cl. 324/693

(57) ABSTRACT

The invention relates to reducing signal distortions occurring when a potential is applied to an electrochemical cell. Electrochemical measurements are obtained in the presence of a specific chemical entity which is an aminoglycoside, an organic polyamine and/or a substance capable of raising the ionic strength of the sample.

### CLAIM OF PRIORITY

The present application is a continuation application based on and claiming priority to PCT Application No. PCT/GB2008/002653, filed Aug. 4, 2008, which claims the priority benefit of British Application No. GB 0715036.0, filed Aug. 2, 2007, each of which are hereby incorporated by reference in their entireties.

### TECHNICAL FIELD OF THE INVENTION

The present invention relates to reducing electrochemical signal distortions occurring when a potential is applied to an electrochemical system.

### BACKGROUND

Electrochemical methodology is a versatile technique well suited to detecting many parameters of a substance. For example; the presence or concentration of a test analyte in a sample can be detected electrochemically by containing the sample in an electrochemical cell, applying a potential across the cell and probing the resulting electrochemical response.

The concentration of an analyte in a sample can be determined by measuring an electrochemical parameter and comparing that measurement with control measurements obtained on samples having known analyte concentrations. For example, in chronoamperometry, a potential difference is applied across an electrochemical cell and the time-dependent current response (the “current transient”) of the cell is measured. The current transient measured in an electrochemical test is related to current transients obtained for control samples (i.e., samples comprising known amounts of analyte) and so can be used to determine the concentration of the test analyte. In one such method according to WO2006/030170, a time-varying potential is applied to step the potential applied across two electrodes in electrical contact with a target solution between an initial and a final potential. Once the final potential has been substantially attained, the current flowing between the electrodes is sampled. It has been found that measurements of this type can reduce errors associated with the current impulses formed when step potentials are applied to the electrodes.

However, many electrochemical measurements still suffer from signal distortions occurring after a potential has been applied across two electrodes. The distortions take the form of a transient contribution, or “shoulder”, to an electrochemical parameter (e.g., current) that is being measured as a function of time. Such distortions may appear, for example, in the period after a substantially constant potential has been attained. Their magnitude may peak substantially immediately after a potential has been applied or alternatively may increase in value over time, before reaching a maximum value and then decaying. The term shoulder derives from the characteristic shape that the signal distortions often lend to for example, current transients obtained in chronoamperometry measurements. As used herein, the term “shoulder” can refer not only to a clearly visible shoulder in a current transient, but also to any increase occurring to a measured electrochemical parameter in the period after a potential has been applied that constitutes a signal distortion. These shoulders may manifest themselves, for example, as an initial peak and subsequent decay of current after application of a potential in a chronoamperometry experiment.

Because the magnitude of these shoulders and their time-decay characteristics often vary in an unpredictable manner, frequently not related to the concentration of the analyte under study, the errors are difficult to quantify in a conventional experiment. As a consequence, it is hard to compensate for the distortions using data-processing techniques or by simply delaying making measurements for a certain period after a potential has been applied. The presence of these signal distortions can therefore provide a significant hindrance to obtaining quantitatively accurate electrochemical measurements.

As an example, in conventional chronoamperometry experiments undertaken on a microelectrode system the current transients at times shortly after a substantially constant potential has been attained are often strongly influenced by the above-described signal distortions. Thus, it is, necessary to obtain measurements over a sufficiently large time period that the contribution to the signal from the shoulder becomes negligible. This can be achieved by measuring over a large time period, thus biasing towards data after the transient shoulder contribution has decayed away. Alternatively, it can be achieved by obtaining measurements only after these shoulders have decayed sufficiently. In both methods, however, there is a corresponding uncertainty as to at what time is “sufficient” for the shoulder contribution to be negligible in a particular experiment.

Accordingly, there is a need for a new technique that addresses the problems of signal distortions occurring in the system after a potential has been applied to an electrochemical cell.

### SUMMARY

The present invention provides use of one or more chemical entities for reducing or preventing the occurrence of signal distortion in an electrochemical method that involves measurement of a current between at least two electrodes in a cell, which cell is in contact with a sample, wherein:
(a) each chemical entity is an aminoglycoside, an organic polyamine, or a substance capable of raising the ionic strength of said sample, and is typically substantially redox-inactive;
(b) said electrochemical method comprises contacting said sample with a redox agent and said cell, and then applying a potential across the electrodes, which generates a peak current that subsequently decays; and
(c) said one or more chemical entities are for increasing the rate of decay of current from said peak current.

The present invention also provides an electrochemical method that involves measurement of a current between at least two electrodes in a cell, which cell is in contact with a sample, wherein:
(a) said sample is contacted with a redox agent and one or more chemical entities, wherein each chemical entity is an aminoglycoside or an organic polyamine, and is typically substantially redox-inactive;
(b) said electrochemical method comprises applying a potential across the electrodes, which generates a peak current that subsequently decays;
(c) said one or more chemical entities are for increasing the rate of decay of current from said peak current; and
(d) said electrochemical method is for detection of cholesterol or triglyceride present in said sample.

Furthermore, the present invention provides a reagent mixture for use in an electrochemical method as defined above, which reagent mixture comprises:
(a) a redox agent;
(b) one or more chemical entities, wherein each chemical entity is an aminoglycoside or an organic polyamine, and is typically substantially redox-inactive;
(c) cholesterol oxidase, cholesterol dehydrogenase, glycerol dehydrogenase or glycerol phosphate oxidase in combination with glycerol kinase; and optionally one or more of
(d) a surfactant;
(e) a coenzyme;
(f) a cholesterol ester hydrolysing reagent;
(g) a triglyceride hydrolysing reagent; and
(h) a reductase.

Still further, the present invention provides a kit for the determination of the amount of cholesterol or triglyceride in a sample, the kit comprising:
an electrochemical cell comprising at least two electrodes;
reagents (a) to (c) as defined above, and optionally one or more of reagents (d) to (h) as defined above;
a voltage source arranged to selectively apply a voltage across the cell; and
a measurement circuit arranged to obtain measurements of an electrochemical parameter on the cell.

The present inventors have found that the addition of certain chemical entities to an electrochemical sample serves to remove or reduce signal distortions occurring when an electrochemical method is performed on the sample. Said signal distortions are the “shoulders” present in an electrochemical parameter that is measured as a function of time after a potential has been applied across the cell.

An advantage of the present invention is therefore that more accurate quantitative measurements can be obtained from an electrochemical system, because of the reduced contribution to the overall electrochemical response from these signal distortions.

A further advantage of the invention is that by removing, or at least reducing, the shoulders, it becomes possible to obtain electrochemical measurements that are substantially entirely derived from the electrochemical response of the redox system under study. Thus, significantly more reliable measurements are obtainable in, the period after a potential has been applied. Additionally this reduction also means that the measurement can be made at an earlier time point enabling the assay to be completed within a shorter time period.

### BRIEF DESCRIPTION OF THE DRAWINGS

The following detailed description of the embodiments of the present invention can be best understood when read in conjunction with the following drawings, where like structure is indicated with like reference numerals and in which:

FIG. 1 depicts a device according to one embodiment of the present invention.

FIG. 2 shows transient current responses to a plasma sample “A” for reagent mixtures comprising no chemical entity additive, spermidine, gentamycin, and neomycin, respectively.

FIG. 3 shows average current responses as a function of time for various plasma samples for reagent mixtures comprising no chemical entity additive, spermidine, gentamycin and neomycin, respectively.

FIG. 4 shows transient current responses to a plasma sample “K” for reagent mixtures comprising no chemical entity additive, spermine, amikacin, apramycin, paromomycin and streptomycin, respectively.

FIG. 5 shows average current responses as a function of time for various plasma samples for reagent mixtures comprising no chemical entity additive, spermine, amikacin, apramycin, paromomycin and streptomycin, respectively.

FIG. 6 shows the gradients of response to HDL and LDL, versus time for sensors prepared with no chemical entity additive (A), 250 mM LiCl (B), 500 mM LiCl (C) and 750 mM LiCl (D), respectively. HDL and LDL gradients of response are shown with closed and open symbols, respectively.

FIG. 7 shows transient current responses to plasma samples comprising TC values of 7.87 mM (no chemical entity additive; sample. “T”) or 6.46 mM (all chemical entities; sample “T2”) for reagent mixtures comprising no chemical entity additive, NaCl, neomycin and streptomycin, respectively.

FIG. 8 shows the average current responses as a function of time for various plasma samples for reagent mixtures comprising no chemical entity additive, NaCl, neomycin and streptomycin, respectively.

FIG. 9 shows average current responses for various plasma samples for reagent mixtures comprising 150 mM neomycin trisulfate.

FIG. 10 shows a calibration plot of current versus TC (total cholesterol) concentration for sensors containing 150 mM neomycin sulfate, obtained using plasma samples having various TC concentrations.

FIG. 11A shows an experimental transient current response for a plasma sample AA containing no chemical entity additive compared to a theoretical response derived using microband theory.

FIG. 11B shows an experimental transient current response for a plasma sample AA containing 150 mM neomycin sulfate compared to a theoretical response derived using microband theory.

FIG. 11C shows the concentration-dependent effect of neomycin trisulfate in reducing the excess charge of experimental current transients, i.e. the magnitude of the shoulder, in comparison to the excess charge observed for sensors with no additive (A is with no additive, and B, C, D and E are with 25, 50, 100 or 150 mM neomycin trisulfate, respectively).

FIG. 12 shows experimental transient current responses for plasma samples containing 7.5 mM NADH compared to a theoretical response derived using microband theory: (A) sample containing n-heptyl-β-D-glucopyranoside surfactant; (B) sample containing Cymal-4 surfactant.

In order that the present invention may be more readily understood, reference is made to the following detailed descriptions and examples, which are intended to illustrate the present invention, but not limit the scope thereof.

### DETAILED DESCRIPTION OF EMBODIMENTS OF THE PRESENT INVENTION

The following descriptions of the embodiments are merely exemplary in nature and are in no way intended to limit the present invention or its application or uses.

The present invention is useful in the electrochemical analysis of a test analyte comprised in a sample. Suitable samples include biological and non-biological substances, including water, beer, wine, blood, plasma, sweat, tears and urine samples. Typically, the sample is an aqueous sample. Suitable test analytes include transition metals and their salts, heavy metals, and physiological species such as enzymes, cholesterol, triglycerides, cations, anions, biomarkers and biological analytes of clinical interest. In one embodiment, the electrochemical method is for the detection of cholesterol or triglyceride. Cholesterol may be total cholesterol, HDL cholesterol or LDL cholesterol.

Electrochemical methods to which the present invention can be applied include any electrochemical method where a signal distortion may occur after a potential has been-applied across the electrodes. Typically, therefore, the electrochemical method involves applying a potential across the cell and measuring the electrochemical response, namely the current response. Typically, the potential applied across the electrodes is, a substantially constant potential or a constant potential. As would be understood by those skilled in the art, a substantially constant potential or constant potential can be attained over a short period of time, the precise period being subject to the specific configuration of the cell.

The signal distortion may manifest itself as a time-dependent contribution to the electrochemical response occurring in the period after a potential is applied across the cell. The signal distortion may reach its maximum value immediately (or substantially immediately) after the potential is applied, or may increase in magnitude over time, before reaching a maximum and then decaying. The electrochemical measurement itself might be obtained in the period after (for example, immediately after) a substantially constant potential has been attained across the electrodes. An electrochemical technique where the present invention is particularly useful is chronoamperometry.

For example, the present invention can be used in any electrochemical measurement in which a steady-state or substantially steady state current is achieved following application of a potential. The present invention can be applied to microelectrode systems such as microband electrode systems and to microelectrode systems, non-exhaustive examples being thin layer cells, flow cells and rotating disc electrodes. The invention can also be used in non steady state electrochemical methods.

The one or more chemical entities of the invention are substances that are capable of reducing the signal distortion occurring after a potential has been applied. They can thus be used to reduce signal distortion in an electrochemical measurement obtained on a sample.

In one embodiment, the chemical entity is an aminoglycoside. Aminoglycosides are a well-known group of chemicals having a common basic structure. Aminoglycosides suitable for use in the present invention include streptomycin, apramycin, paromomycin, amikacin, neomycin, gentamycin, kanamycin, netilmycin and tobramycin. Streptomycin, apramycin, paromomycin, amikacin, neomycin and gentamycin are typical. Streptomycin and neomycin are the most typical.

The chemical entity may alternatively be an organic polyamine. The organic polyamine comprises the elements N, C and H and typically contains only the elements N, C and H. It can comprise primary amine groups (i.e., terminal amine groups) and/or secondary amine groups (i.e., amine groups contained within the chain). It can also comprise tertiary amine groups. In one embodiment, the organic polyamine comprises an organic linear chain polyamine, which is an unbranched organic polyamine. The number of amine groups in the organic polyamine may be from two to twenty, for example from two to five. The number of C-atoms comprised in the polyamine may be from one to one hundred, for example at least three, for example no more than twenty. In one embodiment, the organic polyamine is selected from putrescine, cadaverine, spermidine and spermine, typically spermidine or spermine, most typically spermine.

The aminoglycosides and organic polyamines of the invention are capable of dissolving in an aqueous sample. When so dissolved, these substances are believed to bear at least a partial charge. For example, the dissolved aminoglycosides or polyamines may be charged species. Aminoglycosides or polyamines which form cations in aqueous solution are typical.

Each aminoglycoside or organic polyamine may be present in the cell (e.g. in solution in the sample) in an amount of from 1 to 1000 mM, for example from 20 to 500 mM or 30 to 300 mM, typically from 50 to 200 mM. In one embodiment, each aminoglycoside or organic polyamine is present in the cell in an amount of from 10 to 500 mM.

The chemical entity may alternatively be a substance capable of raising the ionic strength of the sample. The ionic strength of a solution, I_{c}, is given by the equation:

$${I}_{c} = \frac{1}{2} {\sum }_{B = 1}^{n} {c}_{B} {z}_{B}^{2} ,$$

where c_{B} is the molarity concentration of an ion B, z_{B} is the charge of that ion and the summation is over all of the ions present in the solution. In order to capable of increasing the ionic strength of the sample, the substance must therefore be capable of dissolving in aqueous solution to form ions in the sample. Thus, the substance is soluble in aqueous solution. The substance capable of raising the ionic strength of the sample is typically an inorganic salt. Suitable inorganic salts include chlorides, for example LiCl, NaCl, MgCl₂, CaCl₂Cr(NH₃)₆Cl₃ and Co(NH₃)₆Cl₃.

Each inorganic salt may be present in the cell (e.g. in solution in the sample) in an amount of from 0.1 to 5 M, for example from 0.2 to 3 M, typically from 0.2 to 2 M.

The chemical entities of the present invention may thus fall into one of the three classes described above. They may be used in the reagent mixtures and methods of the invention alone or in any combination with one or more different chemical entities of the same and/or different classes.

It has surprisingly been found that the chemical entities described above can reduce the shoulders appearing in current transients obtained after a potential is applied across an electrochemical cell.

One possible explanation for this behaviour is that the chemical entities reduce pseudocapacitance effects on the surface of at least one of the electrodes in the cell. Pseudocapacitance is an electrochemical term relating to the electrochemistry of surface-active groups on an electrode surface and may be at least partially responsible for the signal distortions observed when a potential is applied to the electrodes. Pseudocapacitance comprises both a capacitive term and a resistive term.

In an experiment where the potential is stepped from a first value (which may be zero or non-zero) to a second, non-zero potential, the current resulting from pseudocapacitance can take many seconds to dissipate and so result in a shoulder in a measured transient, for example a current transient. The capacitive term varies according to the material adsorbed on the electrode (for example, surfactant micelles, proteins).

It is thought that aminoglycosides and organic polyamines may be capable of adsorbing preferentially on the electrode surface, therefore disrupting and/or affecting the rate of adsorption of other materials and lowering the capacitive term of the pseudocapacitance. Substances capable of increasing the ionic strength of the solution, such as inorganic salts, may work by lowering the resistance of the solution and thus reducing the resistive term of the pseudocapacitance. Therefore, the inclusion of chemical entities to reduce either or both of the capacitive and resistive terms of the pseudocapacitance would be capable of reducing the observed signal distortions in current transients.

A second possible explanation for this behaviour is that the chemical entities remove or reduce the number of nucleation sites, therefore removing the possibility of nucleation-growth cycles. Such processes have been extensively studied by M. Fleischman et al. (m, for example, J. Electroanalytical Chemistry 1966, 11, p. 205).

The presence of these shoulders is a complex process involving a variety of factors and their interactions in the electrochemical cell and with the electrodes (see, for example, Instrumental methods in electrochemistry, Horwood publishing, 2001, section 2.4.4, page 67). Such factors involve not only the electrode surfaces, but also the impact of surface-active agents and processes such as freeze drying, laser drilling of the electrodes and reagent mixing

It is to be understood, however, that the present invention is not bound by these theories.

Use of one or more chemical entities in accordance with the present invention allows an electrochemical measurement of current having reduced signal distortion to be obtained on a sample. Thus, by use of the present invention, the skilled person is able to reduce or prevent the occurrence of signal distortion in an electrochemical measurement.

Signal distortion is a quantitative error that alters the electrochemical response (the “signal”) of an electrochemical system to an applied potential. Typically, the magnitude of the signal distortion varies as a function of the time after a potential has been applied. The signal distortion may thus be a transient error in the current measurement occurring after a potential has been applied across the cell. Typically, the signal distortion is an increase in observed current in the period after a potential has been applied (i.e. a current “shoulder”). The signal distortion is typically a current shoulder which occurs after the initial peak current and before the normal electrochemical response alone is observed (e.g. before a steady-state (or substantially steady state) current is achieved).

The reduction or prevention of the signal distortion resulting from the addition of the chemical entities of the invention to the sample is accordingly a reduced or eliminated quantitative error in the measured electrochemical response. Typically, the reduced or eliminated signal distortion is observed as a smaller, or absent, current shoulder in a chronoamperometric measurement. The reduced signal distortion may alternatively or additionally be observed as a more rapidly decaying shoulder in a chronoamperometric measurement. Thus, a reduction in signal distortion is observable as an increased rate of decay of current from the current peak generated after a potential is applied across the electrodes (i.e., because the magnitude of the shoulder contribution to the overall current is reduced).

It is understood by those skilled in the art that a non-Faradaic, purely electrical and short-lived charging peak typically exists in a current transient following application of a potential. Generally, measurements recorded for analytical use are therefore obtained after the electrical charging peak has decayed. Such charging peaks typically decay to negligible levels by a maximum of 0.2 seconds after application of the potential, for example by 0.1 seconds or 0.05 seconds after application of the potential. It is to be stressed that the reduction in signal distortion achieved by the present invention is not limited to reducing signal distortion in this very short period of the non-Faradaic charging peak. On the contrary, the increased rate of decay of current from the overall current peak is typically observable at least 0.05 seconds after application of the potential (i.e., after any effects caused by the presence or absence of a charging peak would become negligible). Typically, said increased rate of decay is observable at least 0.1 seconds after application of the potential and can be at least 0.2 seconds after application of the potential.

In a further embodiment, the invention relates to use of one or more chemical entities for reducing or preventing the occurrence of signal distortion in an electrochemical method that involves measurement of a current between, at least two electrodes in a cell, which cell is in contact with a sample, wherein:
(a) each chemical entity is substantially redox-inactive and is an aminoglycoside, an organic polyamine, or a substance capable of raising the ionic strength of the sample;
(b) said electrochemical method comprises contacting said sample with a redox agent and said cell, and then applying a potential across the electrodes; and
(c) said signal distortion is an enhancement of the current, for at least a part of the time from zero to ten seconds after application of the potential, above a predicted current derivable by:
   (i) determining the relationship between the current and time in a period of time beginning at least ten seconds after application of the potential; and
   (ii) using that relationship to extrapolate a predicted current for the period of time from application of the potential to ten seconds after application of the potential.

In this embodiment, therefore, the signal distortion is observable as an enhancement of the current in a period before ten seconds after application of the potential. Typically, this enhancement of the current is observable at least 0.05 seconds after application of the potentially, possibly at least 0.1 seconds after application of the potentially, for example at least 0.2 seconds after application of the potential. The enhancement is an increase in the current compared to the current that can be predicted by first determining the relationship between the current and time in a period of time beginning at least ten seconds after application of the potential and then extrapolating this relationship back to the period of interest before ten seconds. The relationship between current and time in the period after ten seconds can be determined entirely empirically on the basis of data obtained in one or more experiments, or alternatively can be obtained with reference to well known equations predicting the current response to an applied potential for a particular class of system. For example, according to Electrochemical Methods: Fundamentals and Applications, A. J Bard and L. R. Faulkner, John Wiley & Sons, New York, 2^{nd} Edition, 2001, Chapter 5, page 175 and to Journal of Electroanalytical Chemistry, Issue 217, 1987, pages 417-423, a simple theoretical equation exists for the amperometric oxidation current observable at a microband electrode at a given experimental time and applied potential:

$$I = \frac{2 π {AnFD}_{ox} [ Ox ]}{w ln ( 64 \frac{{D}_{ox} t}{{w}^{2}} )} ,$$

where I is the microband current, F is a constant, A is the electrode area, n is the number of electrons involved in the electrochemical reaction, Dₒₓ is the diffusion coefficient of the oxidisable redox agent, [Ox] is the concentration of the oxidisable redox agent, w is the width of the microband electrode and t is the time. It will be appreciated that analogous well-known equations can be applied to electrochemical systems other than those comprising a microband electrode (for example, the Cottrell equation in the case of a planar working electrode). In one embodiment, the relationship between the current and time is obtained in a period of time beginning at least twelve seconds after application of the potential, for example at least fifteen seconds after application of the potential.

The reduction or prevention of the occurrence of signal distortion is confirmed in the Examples described herein by the comparison of a measurement obtained in the presence of a chemical entity of the invention and a measurement obtained on the same system, but without the presence of the chemical entity.

While the signal distortions addressed by the present invention manifest themselves as distortions in the current generated at a particular time after a potential has been applied, it will be appreciated that approaches to quantifying them are not limited to observing the current transient directly. Thus, the chemical entities of the present invention may, for example, increase the rate of decay of current from a peak current or reduce the magnitude of current enhancements relative to extrapolated values of the current predicted using current information beyond the period where the distortion occurs. However, in another embodiment the reduction in signal distortion is observed as a reduction in the total charge passed through the system when the chemical entities are present compared to that when they are not. The total charge passed is proportional to the integral of current generated over time, and so can represent a convenient means of investigating the reduction or prevention of a shoulder period. Thus, in a specific embodiment of the invention the chemical entities are for decreasing the total charge generated when the potential is applied. The total charge generated is typically calculated by integrating from at least 0.05 seconds after application of the potential, and can be at least 0.1 seconds after application of the potential (for example, 0.2 seconds after application of the potential). Furthermore, the total charge generated is typically calculated by integrating up to at least two seconds after application of the potential, and typically at least five seconds after application of the potential, for example at least eight seconds.

Similarly, in a further specific embodiment where the signal distortion is quantified as an enhancement of current, the current enhancement can itself be quantified as an increase in the total charge generated after application of the potential by integration of current over time (for example, between the integration limits described above).

In the present, invention, the sample comes into contact with one dr more chemical entities of the invention. The one or more chemical entities, may be contained in an electrochemical cell and the sample contacted with it by applying the sample to the cell. However, it is also possible that the sample and the one or more chemical entities are contacted outside the cell and then applied to the cell subsequently.

The electrochemical measurement is made on the sample in the presence of the one or more chemical entities. Typically the electrochemical current response results either from a substance present in the sample (i.e., an analyte) or it results from a product formed by a reaction between a substance present in the sample (the analyte) and one or more other substances comprised in the cell (suitable other substances are further described below). The one or more chemical entities typically do not chemically react with the analyte or with any other substances present with which the analyte may react. Nor do the chemical entities themselves typically give any electrochemical response to a potential applied across the electrochemical cell.

Accordingly, each chemical entity is typically substantially redox-inactive. This means that each chemical entity is not oxidised or reduced to a substantial extent either when it is contacted with the sample (which comprises a redox agent and possibly other redox-active compounds) or when the potential is applied across the electrodes. Accordingly, the chemical entities generally do not directly produce a current response when the potential is applied and nor do they indirectly produce a current response by undergoing a redox reaction with a redox-active compound in the sample (for example, the redox agent), whereupon that redox-active compound produces a current response when the potential is applied. It will be appreciated that by “redox-inactive”, it is meant that the chemical entity is redox-inactive under the particular conditions of the electrochemical method being performed. Thus, the chemical entity might, for example, be capable of being oxidised or reduced at an applied potential above or below a certain value. However, provided the potential applied in a particular embodiment does not reach that value, the chemical entity will satisfy the requirement to be redox-inactive within the meaning of the invention (because it will not be oxidised or reduced under those conditions).

The electrochemical method typically involves applying a potential across an electrochemical cell comprising the sample and the one or more chemical entities and measuring the resulting electrochemical current response of the substances comprised in the cell. The electrochemical measurement may be a chronoamperometric current transient in which potential is stepped from an initial potential to a final potential and the current transient recorded once the final potential has been substantially attained. The signal distortion thus corresponds to a distortion of said current transient. In one embodiment, the measured electrochemical response is used to determine the amount of a test analyte present in the sample.

Typically, in the present invention the sample is tested in the presence of a redox agent. Said redox material is an electroactive substance capable of being oxidised or reduced to form a product, which on contact with the sample interacts with the analyte such that it is present in a concentration that is related to the concentration of the analyte. It therefore acts as a mediator, first being oxidised or reduced by the analyte (either directly, or via one or more intermediate species such as an electrocatalyst, which is typically at least one enzyme) to form a product and then, on application of the potential, being reduced or oxidised to give rise to the electrochemical response of the cell.

The redox agent is usually different from each of the one or more chemical entities. However, in one embodiment at least one of the one or more chemical entities is itself a redox agent (for example, the present invention may make use of a single chemical entity, which is itself a redox agent). The dual roles of the redox agent may be a result of increasing the ionic strength of the sample, for example primarily from the anion.

The redox agent may be a molecule or an ionic complex. It may be a naturally occurring electron acceptor such as a protein or may be a synthetic molecule. The redox agent will have at least two oxidation states.

In one embodiment, the redox agent is an inorganic complex. The agent may comprise a metallic ion and may have at least two valencies. In particular, the agent may comprise a transition metal ion. Typical metal ions include those of cobalt, copper, iron, chromium, manganese, nickel, osmium and ruthenium. The redox agent may be charged; for example, it may be cationic or alternatively anionic. An example of a suitable cationic agent is a ruthenium complex such as Ru(NH₃)₆³⁺. An example of a suitable anionic agent is a ferricyanide complex such as Fe(CN)₆³⁻.

Examples of complexes which may be used include Cu(EDTA)²⁻, Fe(CN)₆³⁻, Fe(CN)₅(O₂CR)³⁻. Fe(CN)₄(oxalate)³⁻, Ru(NH₃)₆³⁺ and chelating amine ligand derivatives thereof (such as ethylenediamine), Ru(NH₃)₅(py)³⁺, cis-[bis(2,4-dioxopentan-3-ido)bis(3-pyridine carboxylic acid)-Ruthenium (III)], ferrocenium and derivatives thereof with one or more of groups such as —NH₂, —NHR, —NHC(O)R, for example, ferrocenium monocarboxylic acid (FMCA), and —CO₂H substituted into one or both of the two cyclopentadienyl rings. Another suitable redox agent is [Ru(III)(Me₃TACN)(acac)(1-MeIm)](NO₃)₂, where “TACN” is 1,4,7-Triazacyclononane.

Further suitable redox agents are disclosed in. WO2007/072018, the contents of which are herein incorporated by reference in their entirety. Examples of such complexes are those of the formula

[M(A)ₓ(B)_{y}]^{m}(X^{z})ₙ

wherein M is ruthenium or osmium and has an oxidation state of 0, 1, 2, 3 or 4; x and n are independently an integer selected from 1 to 6; y is an integer selected from 1 to 5; m is an integer from −5 to +4 and z is an integer from −2 to +1;
A is a mono- or bidentate aromatic ligand containing 1 or 2 nitrogen atoms;
B is independently selected to be any suitable ligand other than a heterocyclic nitrogen-containing ligand;
X is any suitable counter ion; wherein A is optionally substituted by 1 to 8 groups independently selected from substituted or unsubstituted alkyl, alkenyl, or aryl groups —F, —Cl, —Br, —I, —NO₂, —CN, —CO₂H, —SO₃H, —NHNH₂, —SH, aryl, alkoxycarbonyl, alkylaminocarbonyl, dialkylaminocarbonyl, —OH, alkoxy, —NH₂, alkylamino, dialkylamino, alkanoylamino, arylcarboxamido, hydrazino, alkylhydrazino, hydroxylamino, alkoxyamino, alkylthio; wherein the number of coordinating atoms is 6.

Further examples of such complexes are those of formula

[M(A)ₓ(B)_{y}]^{m}(X^{z})ₙ

wherein M is ruthenium or osmium and has an oxidation state of 0, 1, 2, 3 or 4; x and n are independently an integer selected from 1-6; y is an integer selected, from 0-5; m is an integer from −5 to +4 and z is an integer from −2 to +1; A is a bi-, tri-, tetra-, penta- or hexadentate ligand which can be either linear having the formula R₁RN(C₂H₄NR)_{w}R¹ or cyclic having the formulae (RNC₂H₄)ᵥ, (RNC₂H₄)ₚ(RNC₃H₆)_{q}, or [(RNC₂H₄XRNC₃H₆)]₅, wherein w is an integer from 1-5, v is an integer from 3-6, p and q are integers from 1-3 whereby the sum of p and q is 4, 5 or 6, and s is either 2 or 3, and wherein R and R¹ are either hydrogen or methyl; B is independently selected to be any suitable ligand; X is any suitable counter ion; wherein B is optionally substituted by 1-8 groups independently selected from substituted or unsubstituted alkyl, alkenyl, or aryl groups —F, —Cl, —Br, —I, —NO₂, —CN, —CO₂H, —SO₃H, —NHNH₂, —SH, aryl, alkoxycarbonyl, alkylaminocarbonyl, dialkylaminocarbonyl, —OH, alkoxy, —NH₂, alkylamino, dialkylamino, alkanoylamino, arylcarboxamido, hydrazino, alkylhydrazino, hydroxylamino, alkoxyamino, alkylthio; wherein the number of coordinating atoms is 6.

It is also possible that the invention is carried out in the further presence of one or more additional reagents useful in carrying out the electrochemical test. For example, one or more electrocatalysts, which catalyse a reaction between the analyte and the redox agent may be used. Typically, the electrocatalyst(s) is at least one enzyme. Surfactants, buffers, excipients and stabilisers may also be used. For example, a surfactant may be used in order to disrupt aggregates or break down bound complexes that may exist in the sample. As is described in detail in WO12006/067424, a surfactant can be particularly useful where certain physiological samples are used.

The one or more chemical entities, redox agent and optional further ingredients may be each be provided to the electrochemical cell in advance of the sample, or a mixture of the reagents with the sample may be formed and this mixture provided to the electrochemical cell. Further, the one or more chemical entities, redox agent and optional further ingredients may be provided separately, or one or more of these reagents may be provided in the form of a reagent mixture. In one embodiment, all of the necessary reagents for obtaining the electrochemical measurement are provided in the form of a single reagent mixture. In another embodiment where the sample is blood, the cell comprises a blood separation membrane through which the sample passes before contacting the electrodes. In such an embodiment, the one or more chemical entities can be associated with the blood separation membrane, such that the sample is dosed with the chemical entity as it contacts, the membrane.

The reagent mixture described above typically comprises at least one chemical entity as defined above and a redox agent as defined above. Each aminoglycoside or organic polyamine is typically present in the reagent mixture in an amount of from 1 to 1000 mM. In one embodiment, each aminoglycoside or organic polyamine is present in an amount of from 1.0 to 500 mM, for example from 20 to 500 mM or 30 to 300 mM, or from 50 to 200 mM. Each inorganic salt is typically present in the reagent mixture in an amount of from 0.1 to 5 M, for example from 0.2 to 3 M, or from 0.2 to 2 M, or from 0.2 to 0.75 M. The redox agent is typically present in the reagent mixture in an amount of from 0.1 to 400 mM, for example from 10 to 200 mM, from 30 to 150 mM, or from 50 to 100 mM.

The reagent mixture may additionally comprise other components such as further reagents that are involved in the interaction between the redox material and the analyte. Examples of such further reagents are electrocatalysts, surfactants, buffers, excipients and stabilisers as discussed in more detail below. Typically, any electrocatalysts present are enzymes.

One specific embodiment of the invention relates to a reagent mixture suitable for use in carrying out a cholesterol or triglyceride test. A cholesterol test may be a test for HDL cholesterol, LDL cholesterol, or total cholesterol present in the sample. Enzymes suitable for use in detecting triglyceride in a sample include glycerol dehydrogenase or glycerol phosphate oxidase in combination with glycerol kinase, which may be used in conjunction in with the redox agents of the invention and optionally further reagents. An enzyme such as cholesterol oxidase or cholesterol dehydrogenase is suitable for use in detecting cholesterol. Detailed descriptions of reagent mixtures and methods suitable for carrying out cholesterol (HDL, LDL or total) tests are described in WO2007/072013, WO 2006/067424, WO 2007/132223 and WO 2007/132226, the contents of all of which are herein incorporated by reference in their entirety. The reagent mixture of the invention comprises the redox agent, the one or more chemical entities and at least one enzyme, wherein said at least one enzyme is selected from cholesterol oxidase, cholesterol dehydrogenase, glycerol dehydrogenase and glycerol phosphate oxidase in combination with glycerol kinase. The reagent mixture may also comprise one or more of a surfactant, a coenzyme, a cholesterol ester hydrolysing agent, a triglyceride hydrolysing agent and a reductase. In one embodiment, the reagent mixture comprises a surfactant.

A surfactant can be used in order to break down lipoproteins to which triglycerides, cholesterol or cholesterol esters are incorporated. Examples of surfactants suitable for use in the present invention include polyoxyethylene derivatives such as polyoxyethylene alkylene tribenzyl phenyl ether and polyoxyethylene alkylene phenyl ether, sucrose esters, maltosides, hydroxyethylglucamide derivatives, N-methyl-N-acyl glucamine derivatives and bile acid derivatives (or salts thereof). Typical surfactants include sucrose monocaprate (“SMC”), Anameg-7 (Anatrace A340) and bile acid derivatives. Surfactants are typically used in an amount of up to 1000 mg per ml of reagent mixture, in one embodiment up to 500 mg/ml, for example up to or at least 50 mg/ml, for example from 3 to 200 mg/ml.

The cholesterol contained in lipoproteins may be in the form of free cholesterol or cholesterol esters. A cholesterol ester hydrolysing reagent may therefore be used to break down any cholesterol esters into free cholesterol. The free cholesterol is then reacted with an enzyme such as cholesterol oxidase or cholesterol dehydrogenase and the amount of cholesterol which has undergone such reaction is measured using the method of the invention.

The cholesterol ester hydrolysing reagent may be any reagent capable of hydrolysing cholesterol esters to cholesterol. The reagent should be one which does not interfere with the reaction of cholesterol with cholesterol oxidase or cholesterol dehydrogenase. In one embodiment, cholesterol ester hydrolysing reagents are enzymes, for example cholesterol esterase and lipases. Lipases are particularly suitable. A suitable lipase is, for example, a lipase from a pseudomonas or chromobacterium viscosum species. Commercially available enzymes, optionally containing additives such as stabilisers or preservatives may be used, e.g. those available from Toyobo or Amano. In one embodiment, the cholesterol ester hydrolysing reagent may be used in an amount of from 0.1 to 25 mg per ml of reagent mixture, for example from 0.1 to 20 mg per ml of reagent mixture, suitably from 0.5 to 25 mg per ml, such as from 0.5 to 15 mg per ml. In another embodiment, the cholesterol ester hydrolysing reagent may be used in an amount of from 0.1 to 100 mg per ml of reagent mixture, suitably from 0.5 to 50 mg per nil. In this embodiment, the cholesterol ester hydrolysing reagent can be a lipase.

In the case of a triglyceride test, a triglyceride hydrolysing reagent is typically used in order to hydrolyse triglyceride to glycerol. The reagents used are typically those described above as cholesterol ester hydrolysing, reagents.

Any commercially available forms of glycerol dehydrogenase, glycerol phosphate oxidase, glycerol kinase, cholesterol oxidase and cholesterol dehydrogenase may be employed. For instance, the cholesterol dehydrogenase is, for example, from the Nocardia species. The oxidase or dehydrogenase may be used in an amount of from 0.01 mg to 100 mg per ml of reagent mixture. In one embodiment, the oxidase or dehydrogenase is used in an amount of from 0.1 to 50 mg per ml of reagent mixture, suitably from 0.5 to 25 mg per ml. In one embodiment, the glycerol kinase is present in an amount of from 450 U/ml reagent mixture to 45000 U/ml reagent mixture.

The coenzyme is capable of being reversibly oxidised and reduced. Typically, the coenzyme becomes oxidised or reduced by reducing or oxidising the test analyte in the sample via the cholesterol oxidase or cholesterol dehydrogenase. The coenzyme then oxidises or reduces the redox agent (either directly or via one or more intermediate species). An example of such an assay is shown below:

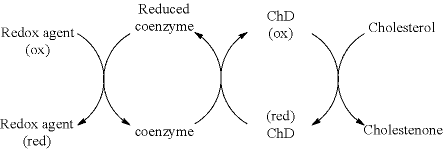

where ChD is cholesterol dehydrogenase. Thus, cholesterol is oxidised to cholestenone by cholesterol dehydrogenase, which is oxidised by the coenzyme, which is then oxidised by the redox agent. The amount of reduced redox agent produced by the assay (the “product”) can then be detected electrochemically, by applying a potential across the cell and measuring the electrochemical response. Cholesterol dehydrogenase could be replaced with cholesterol oxidase in this assay if desired.

Suitable coenzymes include NAD⁺ or an analogue thereof such as APAD (Acetyl pyridine adenine dinucleotide), TNAD (Thio-NAD), AHD (acetyl pyridine hypoxanthine dinucleotide), NaAD (nicotinic acid adenine dinucleotide), NHD (nicotinamide hypoxanthine dinucleotide), or NGD (nicotinamide guanine dinucleotide). The coenzyme is typically present in the reagent mixture in an amount of from 1 to 25 mM, for example from 3 to 15 mM, suitably from 5 to 10 mM.

The reductase typically accepts a hydride from the reduced coenzyme and subsequently transfers two electrons to the redox agent; this can occur in either one or two steps depending on the redox agent. The use of a reductase therefore provides swift electron transfer. Examples of reductases which can be used include diaphorase and cytochrome P450 reductases, in particular, the putidaredoxin reductase of the cytochrome P450_{com} enzyme system from Pseudomonas putida, the flavin (FAD/FMN) domain of the P450_{BM-3} enzyme from Bacillus megaterium, spinach ferrodoxin reductase, rubredoxin reductase, adrenodoxin reductase, nitrate reductase, cytochrome b₅ reductase, corn nitrate reductase, terpredoxin reductase and yeast, rat, rabbit and human NADPH cytochrome P450 reductases. Where a nitrate reductase is employed, typically corn nitrate reductase is used. Suitable reductases for use in the present invention include diaphorase and putidaredoxin reductases.

The reductase may be a recombinant protein or a naturally occurring protein which has been purified or isolated. The reductase may have been mutated to improve its performance such as to optimize the speed at which it carries out the electron transfer or its substrate specificity.

The reductase is typically present in the reagent mixture in an amount of from 0.5 to 100 mg/ml, for example from 1 to 50 mg/ml, 1 to 30 mg/ml or from 5 to 20 mg/ml.

As hereinbefore described, in one aspect the present invention relates to use of one or more chemical entities for reducing or preventing signal distortion in an electrochemical method. In a further more specific embodiment, the present invention relates to an electrochemical method for detection of cholesterol or triglyceride. This method involves measurement in a cell of a current between at least two electrodes, one of which is in contact with a sample. In this method, the sample is contacted with a redox agent as described above and one or more chemical entities as described above. Furthermore, as this method is for detection of cholesterol or triglyceride, typically it will involve use of reagents specifically adapted for the purpose of detecting such an analyte. For example, the method typically involves contacting the sample with at least one enzyme, wherein said at least one enzyme is selected from cholesterol oxidase and cholesterol dehydrogenase (for detection of cholesterol) or glycerol dehydrogenase and glycerol phosphate oxidase in combination with glycerol kinase (for detection of triglyceride). Furthermore, the sample may be also be contacted with one or more of a surfactant, a coenzyme, a cholesterol ester hydrolysing agent and a reductase, wherein each of these species can be as hereinbefore described.

The method of the present invention allows cholesterol or triglyceride to be detected. For example, the amount of cholesterol or triglyceride can be quantitatively determined. The presence of the one or more chemical entities ensures that the signal distortion occurring in such a method is reduced or prevented.

Still further, the present invention provides a kit for determining the amount of cholesterol or triglyceride in a sample. The kit comprises at least (a) a redox agent, (b) one or more chemical entities and (c) cholesterol oxidase or cholesterol dehydrogenase (for detection of cholesterol) or glycerol dehydrogenase or glycerol phosphate oxidase in combination with glycerol kinase (for detection of triglyceride). The kit may optionally further comprise additional reagents as described above. For example, the kit may comprise the reagent mixture of the invention. The kit additionally includes a device comprising:
an electrochemical cell comprising at least two electrodes;
a voltage source arranged to selectively apply a voltage across the cell; and
a measurement circuit arranged to obtain measurements of an electrochemical parameter on the cell.

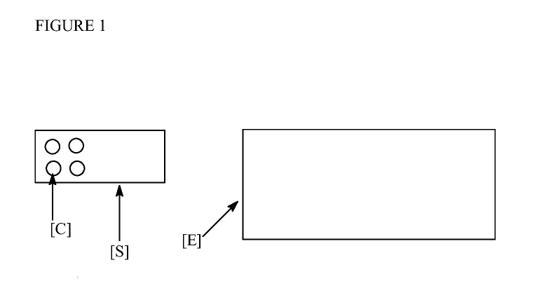

A device according to one embodiment of the invention is depicted in FIG. 1. In this embodiment, the device comprises a strip [S] comprising four electrochemical cells [C] and an electronics unit [E], e.g. a hand-held portable electronics unit, capable of forming electronic contact with the strip [S]. The electronics unit [E] may, for example, house a power supply for providing a potential to the electrodes, as well as a measuring instrument for detecting an electrochemical response and any other measuring instruments required. One or more of these systems may be operated by a computer program.

The electrochemical cell [C] may be a two-electrode, a three-electrode, a four-electrode or a multiple-electrode system. A two-electrode system comprises a working electrode and a pseudo reference electrode. A three-electrode system comprises a working electrode, an ideal or a pseudo reference electrode and a separate counter electrode. As used herein, a pseudo reference electrode is an electrode that is capable of providing a substantially stable reference potential. In a two-electrode system, the pseudo reference electrode also acts as the counter electrode. In this case a current passes through it but does not analytically significantly perturb the reference potential. As used herein, an ideal reference electrode is an ideal non-polarisable electrode through which no current passes.

In one embodiment of the invention, the electrochemical cell is in the form of a receptacle. The receptacle may be in any shape as long as it is capable of containing a liquid which is placed into it. For example, the receptacle may be cylindrical. Generally, a receptacle will contain a base and a wall or walls that surround the base. Suitable embodiments of electrochemical cells in the form of receptacles are, for example, disclosed in WO03/056319.

The electrochemical cell may have at least one microelectrode, for example a microband electrode. If so, typically the working electrode is a microelectrode. For the purposes of this invention, a microelectrode is an electrode having at least one dimension that comes into contact with the sample that does not exceed 50 μm. The microelectrodes of the invention may have a dimension that contacts with the sample that is macro in size, i.e. which is greater than 50 μm. A typical microelectrode of the invention has one dimension of 50 μm or less and one dimension of greater than 50 μm (where the dimensions referred to are those in contact with the sample).

For the purposes of this invention, a microband electrode is defined as having one dimension more than 50 μm and one dimension less than 50 μm (where the dimensions referred to are those in contact with the sample). A microband electrode is present in the cell in the shape of a band.

Further details regarding electrochemical cells which can be used in the devices of the present invention can be found in WO2006/000828.

The electronics unit [E] comprises a voltage source arranged to selectively apply a voltage across the cell and a measurement circuit arranged to obtain measurements of an electrochemical parameter on the cell. The unit may also comprise other features, such as a display panel to read out the measured electrochemical parameter.

The devices of the present invention may comprise two or more (e.g. three or four) electrochemical cells. In such an embodiment, a plurality of strips may be used or the strip [S] may itself comprise a plurality of electrochemical cells. This embodiment allows a number of measurements to be taken either substantially simultaneously or in a step-wise fashion. The same or different reagent mixtures can be associated with each of the cells, allowing several identical measurements to be made or, for example, the concentrations of several different analytes in a sample to be measured simultaneously in a single device.

The kit of the present invention is operated by providing a sample and reacting it with the reagent mixture. In one embodiment, the reagent mixture is contained in the electrochemical cell and the sample is contacted with the reagent mixture by placing it in the electrochemical cell. The mixture of the sample and the reagent mixture should be in electrical contact with the working electrode so that electrochemical reaction can occur at the electrode. A potential is then applied across the cell and, typically, the electrochemical response is measured as current transient.

In a further specific embodiment, there is provided a method of obtaining an electrochemical measurement comprising:
contacting a sample with:
   (a) a redox agent capable of being oxidised or reduced to form a product; and
   (b) one or more chemical entities;
   wherein each chemical entity is:
   (i) an aminoglycoside; or
   (ii) an organic polyamine; and
obtaining the electrochemical measurement on the sample, in the presence of (a) and (b).

The aminoglycoside is typically selected from streptomycin, apramycin, paromomycin, amikacin, neomycin and gentamycin. The organic polyamine is typically selected from spermidine and spermine.

Another further specific embodiment relates to a method of reducing or preventing the occurrence of signal distortion in an electrochemical measurement obtained on a sample, which method comprises obtaining said electrochemical measurement in the presence of:

(a) a redox agent capable of being oxidised or reduced to form a product; and
(b) one or more chemical entities;
wherein each chemical entity is:
(i) an aminoglycoside as defined above;
(ii) an organic polyamine as defined above; or
(iii) a substance capable of raising the ionic strength of the sample.

The substance capable of raising the ionic strength of the sample is, typically an inorganic salt, such as an inorganic salt selected from LiCl, NaCl, MgCl₂, CaCl₂ and Cr(NH₃)₆Cl₃.

In the above specific further embodiments the electrochemical measurement can be obtained using an electrochemical cell comprising at least two electrodes, and comprises applying a potential across the cell and measuring the electrochemical response of the substances comprised in the cell; and the signal distortion is a transient error in the electrochemical measurement occurring after a potential has been applied across the electrochemical cell. The signal distortion may be, for example, a contribution to the electrochemical measurement resulting from pseudocapacitance of the electrodes. The electrochemical measurement in one embodiment comprises a chronoamperometric current transient.

Yet another specific embodiment relates to a reagent mixture for use in an electrochemical method performed on a sample, the reagent mixture comprising:

(a) a redox agent capable of being oxidised or reduced to form a product; and
(b) one or more chemical entities;
wherein each chemical entity is:
(i) an aminoglycoside; or
(ii) an organic polyamine.

This reagent mixture in one embodiment comprises (c) a surfactant. The reagent mixture in other embodiments comprises (d) an enzyme and (e) a coenzyme. In yet other embodiments, the reagent mixture comprises one or more of:

(f) a cholesterol ester hydrolysing reagent;
(g) a cholesterol oxidase or cholesterol dehydrogenase; and
(h) a reductase.

Still further, the present invention provides a kit for the determination of the amount of a test analyte in a sample, the kit comprising:
an electrochemical cell comprising at least two electrodes;
reagents (a) and (b) as defined above, and optionally one or more of reagents (c) to (h) as defined above;
a voltage source arranged to selectively apply a voltage across the cell; and
a measurement circuit arranged to obtain measurements of an electrochemical parameter on the cell.

One of the electrodes of said kit is typically a working electrode having at least one dimension of less than 50 μm.

### EXAMPLES

### Handheld Biosensor Device

A device of the type depicted in FIG. 1 and described in detail in WO 2007/072013, having four electrochemical cells comprised in the strip [S], was used. Each electrochemical cell comprised a carbon working electrode and a Ag/AgCl pseudo reference electrode. The volume of each cell was approximately 0.6 μL. Identical deposition solutions were inserted into all four of the cells.

### Plasma Samples

Plasma samples were defrosted for 30 minutes before being centrifuged for 5 minutes at 2900 RCF (Labnet 1618). Delipidated serum (Scipac, S139) was also used as a sample. The samples were analyzed using a Space clinical analyzer (Schiappanelli Biosystems Inc) to obtain their TC (total cholesterol) or HDL (high density lipoprotein) concentrations.

In the Examples 1 to 4 that follow, the concentrations determined by the Space analyzer for each of the samples were as given in Table 1 below.

TABLE 1
Sample I.D.s; Figure number; and HDL/TC concentrations
determined by the Space Analyzer

| | Sample | Figure | |
|---|---|---|---|
| (Example No.) - Mixes in which sample is used | I.D. | number | |
| | | | HDL conc/ |
| | | | mM |
| (1) - No additive and spermidine | A | 2, 3 | 1.86 |
| (1) - No additive and spermidine | D | 3 | 1.68 |
| (1) - No additive and spermidine | B | 3 | 1.35 |
| (1) - No additive and spermidine | E | 3 | 1.32 |
| (1) - No additive and spermidine | G | 3 | 1.27 |
| (1) - No additive and spermidine | C | 3 | 1.20 |
| (1) - No additive and spermidine | F | 3 | 0.92 |
| (1) - Gentamycin and neomycin | A | 2, 3 | 1.78 |
| (1) - Gentamycin and neomycin | D | 3 | 1.54 |
| (1) - Gentamycin and neomycin | H | 3 | 1.20 |
| (1) - Gentamycin and neomycin | B | 3 | 1.19 |
| (1) - Gentamycin and neomycin | E | 3 | 1.11 |
| (1) - Gentamycin and neomycin | C | 3 | 1.09 |
| (1) - Gentamycin and neomycin | F | 3 | 0.84 |
| (2) - No additive, spermine and amikacin | J | 5 | 1.80 |
| (2) - No additive, spermine and amikacin | N | 5 | 1.59 |
| (2) - No additive, spermine and amikacin | M | 5 | 1.48 |
| (2) - No additive, spermine and amikacin | K | 4, 5 | 1.31 |
| (2) - No additive, spermine and amikacin | L | 5 | 1.26 |
| (2) - No additive, spermine and amikacin | O | 5 | 1.21 |
| (2) - Apramycin, paromomycin and streptomycin | J | 5 | 1.75 |
| (2) - Apramycin, paromomycin and streptomycin | N | 5 | 1.57 |
| (2) - Apramycin, paromomycin and streptomycin | K | 4, 5 | 1.40 |
| (2) - Apramycin, paromomycin and streptomycin | P | 5 | 1.34 |
| (2) - Apramycin, paromomycin and streptomycin | L | 5 | 1.19 |
| (2) - Apramycin, paromomycin and streptomycin | O | 5 | 1.10 |
| | | | TC conc/ |
| | | | mM |
| (4) - No additive | T | 7, 8 | 6.46 |
| (4) - No additive | U | 8 | 6.12 |
| (4) - No additive | W | 8 | 4.51 |
| (4) - No additive | R | 8 | 4.05 |
| (4) - No additive | V | 8 | 3.72 |
| (4) - No additive | X | 8 | 3.59 |
| (4) - No additive | S | 8 | 3.18 |
| (4) - NaCl, neomycin and streptomycin | T2 | 7, 8 | 7.87 |
| (4) - NaCl, neomycin and streptomycin | T3 | 8 | 6.96 |
| (4) - NaCl, neomycin and streptomycin | T1 | 8 | 6.07 |
| (4) - NaCl, neomycin and streptomycin | T5 | 8 | 5.86 |
| (4) - NaCl, neomycin and streptomycin | T4 | 8 | 5.22 |
| (4) - NaCl, neomycin and streptomycin | T7 | 8 | 4.29 |
| (4) - NaCl, neomycin and streptomycin | T6 | 8 | 3.70 |

### Example 1

The aim of this Example was to investigate organic polyamines and aminoglycosides for their ability to improve the electrochemical response with a cis-[bis(2,4-dioxopentan-3-ido)bis(3-pyridine carboxylic acid)-Ruthenium (III)] redox agent (herein labeled “RuAcac”), when using screen printed carbon electrodes and a sugar surfactant.

### Deposition Solution (0.4 μL of Aqueous Solution Inserted Per Electrochemical Cell)

0.1 M Tris buffer pH 9.0
10% β-lactose
5% sucrose monocaprate (SMC)

### 30 mM KOH

### 30 mM RuAcac

100 mM chemical entity
8.9 mM thionicotinamide adenine dinucleotide (Oriental Yeast Co)
4.2 mg/ml putidaredoxin reductase (Biocatalysts)
3.3 mg/ml lipase (Genzyme)
22.2 mg/ml cholesterol dehydrogenase, gelatin free (Amano).
This solution was mixed using a Covaris acoustic mixer.

### Chemical Entity

(i) Neomycin sulphate
(ii) Gentamycin sulphate
(iii) Spermidine trihydrochloride.

The dispensed sensor sheets were then placed into a LS40 freeze drier (Severn Science) for freeze drying.

### Testing Protocol

15 μl of plasma sample was used per strip. On the addition of 15 μl of plasma the chronoamperometry test was initiated using a multiplexer (MX452, Sternhagen design) attached to an Autolab (PGSTAT 12) and GPES software (v4.9). An oxidation potential of 0.15 V was immediately applied to the first cell and a 4-second-long current transient was measured. Immediately after this, the same potential was applied to the second cell for 4 seconds, then to the third cell for 4 seconds, and finally to the fourth cell with 4 seconds. Four current transients were therefore obtained, which corresponded to the first “run”, obtained at a “run time” of 0 seconds. At 32 seconds after the initial potential was applied to the first cell, the process was repeated (thus, a further four current transients were obtained for this second run, obtained at a run time of 32 seconds). The process was repeated further at run times of 64, 96, 128, 160, 192, 224, 256, 288, 320, 352 and 384 seconds. Therefore, a total of fifty-two current transients were obtained (for each of the four cells for each of the thirteen runs).

At 416 seconds, a reduction potential of −0.45 V was applied and four final 4-second-long current transients were measured, each transient again corresponding to each of the four cells.

### Results

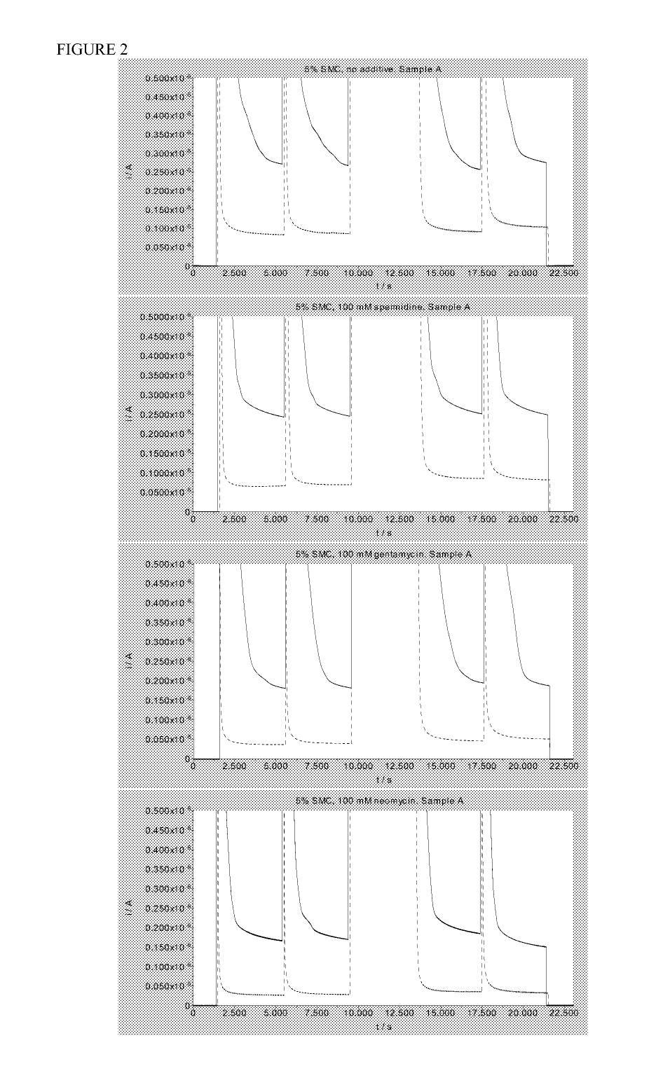

FIG. 2 shows transient current responses to plasma sample “A” (see Table 1) for each of the mixes. Each mix has four transient responses, corresponding to the four identical cells in the sensor. On each graph, two current traces are shown, corresponding to the first and the last of the thirteen runs obtained using the testing protocol described above. In each case, the low trace corresponds to the first current transient obtained (0 seconds), with the high trace corresponding to the final current transient (384 seconds) obtained on the sample. The shoulders on the current transients are clearly visible as enhanced current at close to zero time (i.e., substantially immediately after the oxidation potential is applied), which decay over the duration of the time period such that the current reaches a steady state. This steady state current corresponds to the reactive current (i.e., it results from oxidation of the reduced redox material that has itself been formed by reacting with the sample). The Figure clearly shows that the shoulders are reduced and decay more rapidly when neomycin, gentamycin or spermidine are added to the enzyme mix. Neomycin is seen to be particularly effective.

The magnitudes and durations of the shoulders appearing in the current transients were also subjectively graded on the following basis: a “1” corresponds to a negligible shoulder; a “2” corresponds to an intermediate shoulder (decays before the end of the transient; and a “3” corresponds to a substantial shoulder (has not decayed or has just decayed by the end of the transient).

The gradings assigned to the enzyme+chemical entity reagent mixtures of this Example are shown in Table 2.

TABLE 2
Extent of shoulder for the mixes of Example 1

| Mix | Extent of shoulder |
|---|---|
| 5% SMC no additive | 3 |
| 5% SMC 100 mM neomycin | 1 |
| 5% SMC 100 mM gentamycin | 2 |
| 5% SMC 100 mM spermidine | 2 |

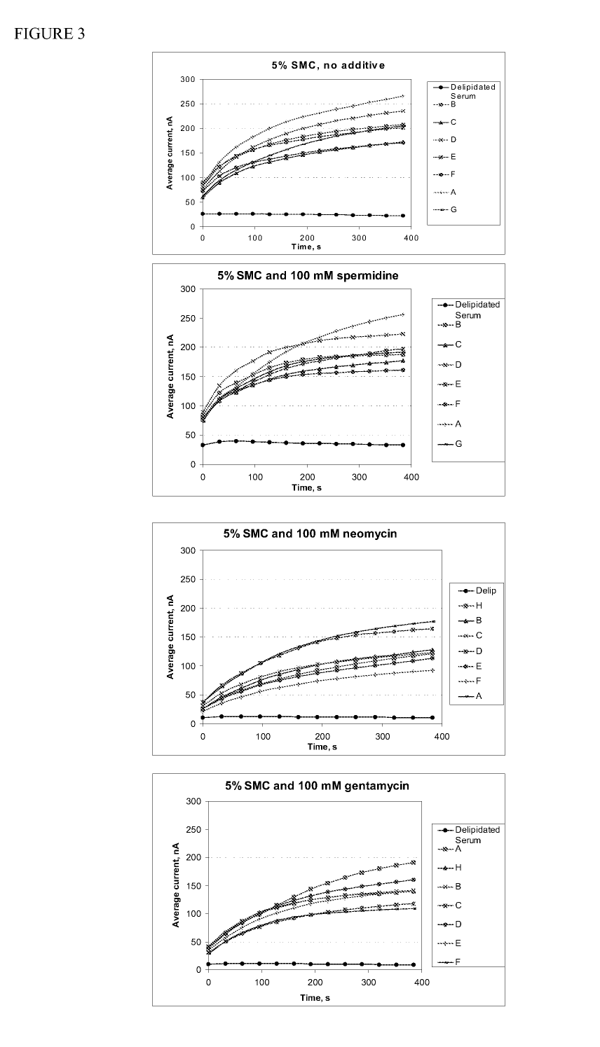

FIG. 3 shows the average current responses i.e., the final current values at the end, of the 4 second current transient as a function of run time for various plasma samples. In each graph, each curve corresponds to a particular plasma sample as indicated. On the curve, each point corresponds to an average over the current transients obtained in each of the four identical cells at that particular run time.

The effect of the shoulder reduction by spermidine, gentamycin and neomycin is clearly manifested as a reduction in the average current response (because it contains a reduced contribution from the shoulder).

### Example 2

The aim of this Example was to further investigate organic linear chain polyamines and aminoglycosides for ability to improve the electrochemical response with RuAcac mediator, when using screen printed carbon electrodes and sugar surfactant.

### Deposition Solution (0.4 Aqueous Solution Inserted Per Electrochemical Cell)

0.1 M Tris buffer pH 9.0
10% β-lactose

### 30 mM KOH

5% sucrose monocaprate (SMC)

### 30 mM RuAcac

100 mM chemical entity
8.9 mM thionicotinamide adenine dinucleotide (Oriental Yeast Co)
4.2 mg/ml putidaredoxin reductase (Biocatalysts)
3.3 mg/ml lipase (Genzyme)
22.2 mg/ml cholesterol dehydrogenase, gelatin free (Amano).

### Chemical Entities

(i) Streptomycin sulfate
(ii) Apramycin sulfate.
(iii) Paromomycin sulfate
(iv) Spermine tetrahydrochloride
(v) Amikacin sulfate.
(vi) No additive

Testing Protocol was performed as in Example 1.

### Results

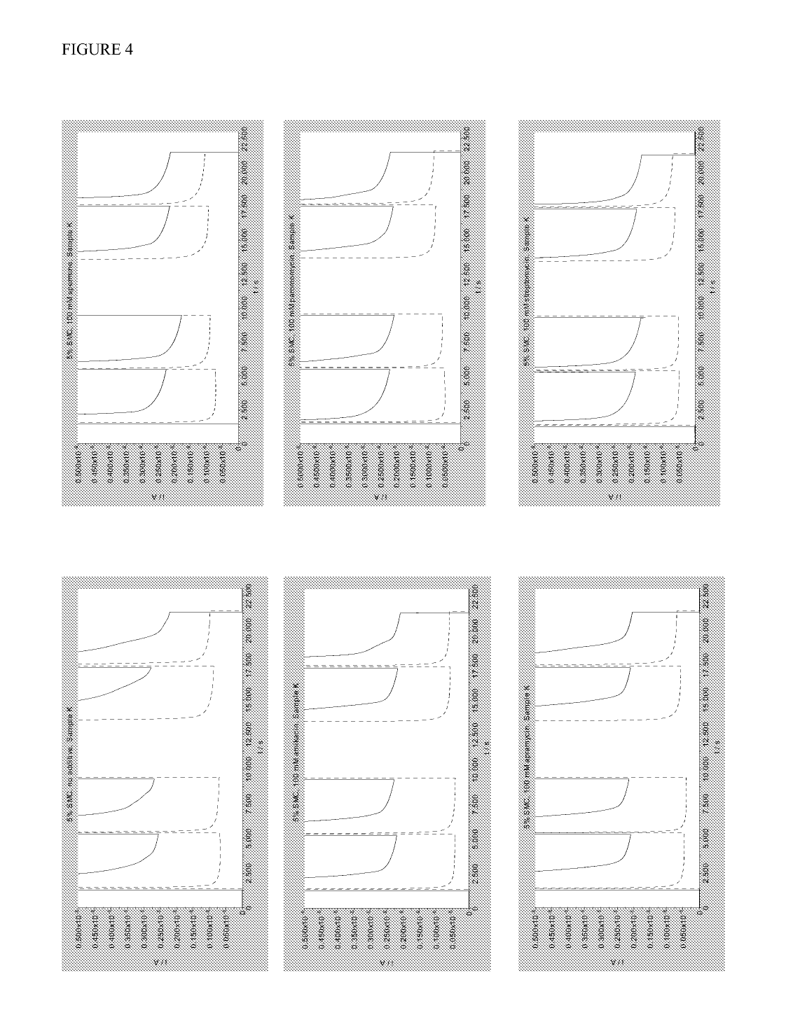

FIG. 4 shows the transient current responses to plasma sample “K” for each of the mixes. As in Example 1, the current transients obtained on the first and last runs only (0 seconds and 384 seconds) are shown for illustrative purposes. As in FIG. 2 of Example 1, this Figure shows that the added chemical entities are capable of reducing the shoulder occurring in the current transients compared to the shoulder observed in the absence of the chemical entity. Streptomycin and spermine are particularly effective.

As in Example 1, the extent of the shoulder was also numerically graded. The results of this grading are shown in Table 3.

TABLE 3
Extent of shoulder for mixes of Example 2

| Mix | Extent of shoulder |
|---|---|
| 5% SMC no additive | 3 |
| 5% SMC 100 mM streptomycin | 1 |
| 5% SMC 100 mM apramycin | 2 |
| 5% SMC 100 mM paromomycin | 2 |
| 5% SMC 100 mM spermine | 1 |
| 5% SMC 100 mM amikacin | 2 |

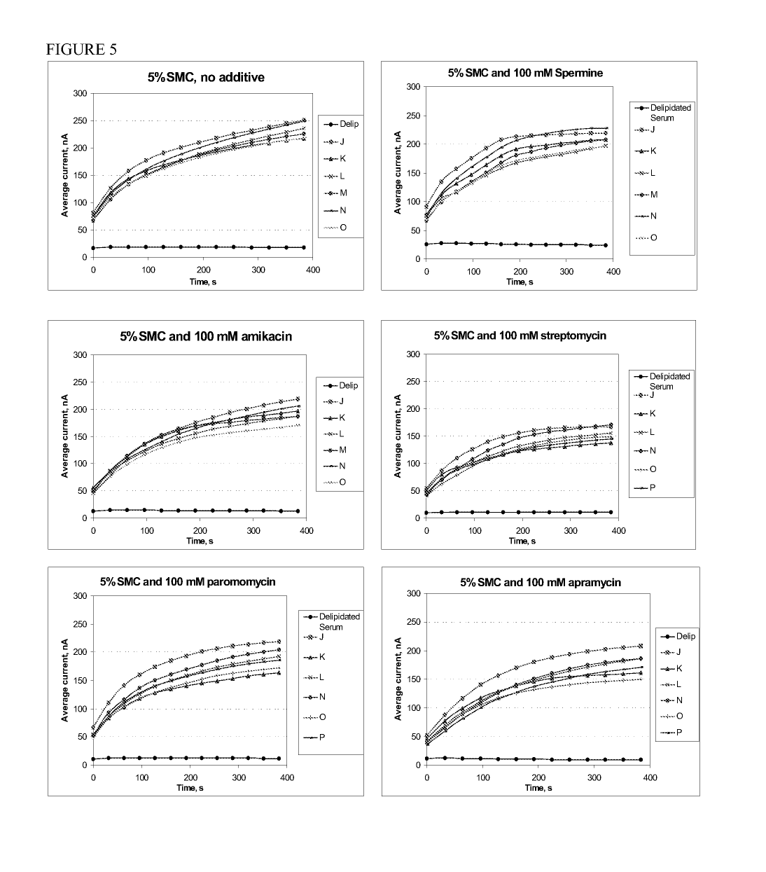

FIG. 5 shows the average current responses as a function of time for various plasma samples. As in FIG. 3 of Example 1, the average current responses corresponding to tests where a chemical entity additive was present are clearly reduced in magnitude (due to a lesser contribution from signal distortion).

### Example 3

The aim of this Example was to investigate the current response to HDL in a sample using sensors prepared with 5% w/v SMC surfactant and various inorganic salts.

### Deposition Solution (0.4 μL Aqueous Solution Inserted Per Electrochemical Cell)

0.1 M Tris buffer pH 9.0
10% β-lactose

### 30 mM KOH

5% sucrose monocaprate (SMC)

### 30 mM RuAcac

x mM inorganic salt
8.9 mM thionicotinamide adenine dinucleotide (Oriental Yeast Co)
4.2 mg/ml putidaredoxin reductase (Biocatalysts)
3.3 mg/ml lipase (Genzyme)
22.2 mg/ml cholesterol dehydrogenase, gelatin free (Amano).

### Inorganic Salts

### (i) 0.25, 0.5 or 0.75 M LiCl

### (ii) 50, 500 mM NaCl

(iii) 280 mM MgCl₂

### (iv) 125 mM CaCl₂

### (v) 250 mM CaCl₂

### (vi) 60 or 15 mM Cr(NH₃)₆Cl₃

(vii) no additive

Testing Protocol was again performed as in Example 1.

The use of inorganic salt in the enzyme mix was found to decrease the length of time taken for the sensor to have a maximum gradient of response to HDL. The “gradient of response” to HDL at a given one of the thirteen run times at which oxidative potentials were applied to the cells in turn was obtained by constructing, from the data at each run time, a calibration curve of average current responses of the sensor versus HDL concentration (obtained by testing different plasma samples). The gradient of response is the gradient of the line-of-best-fit through the data points.

The time points at which of the sensor types gave maximum gradient of response to HDL are given in Table 4 below.

TABLE 4
Time of maximum HDL gradient of
response for mixes of Example 3

| | Time at which HDL gradient reaches |
|---|---|
| Mix | maximum value/sec |
| 5% SMC no additive | 384 |
| 5% SMC & 250 mM LiCl | 192 |
| 5% SMC & 500 mM LiCl | 160 |
| 5% SMC & 750 mM LiCl | 256 |
| 5% SMC no additive | 352 |
| 5% SMC & 50 mM NaCl | 224 |
| 5% SMC & 500 mM NaCl | 160 |
| 5% SMC & 125 mM CaCl₂ | 224 |
| 5% SMC & 250 mM CaCl₂ | 288 |
| 5% SMC no additive | 384 |
| 5% SMC & 280 mM MgCl₂ | 256 |
| 5% SMC no additive | 352 |
| 5% SMC & 15 mM Cr(NH₃)₆Cl₃ | 192 |
| 5% SMC & 60 mM Cr(NH₃)₆Cl₃ | 96 |

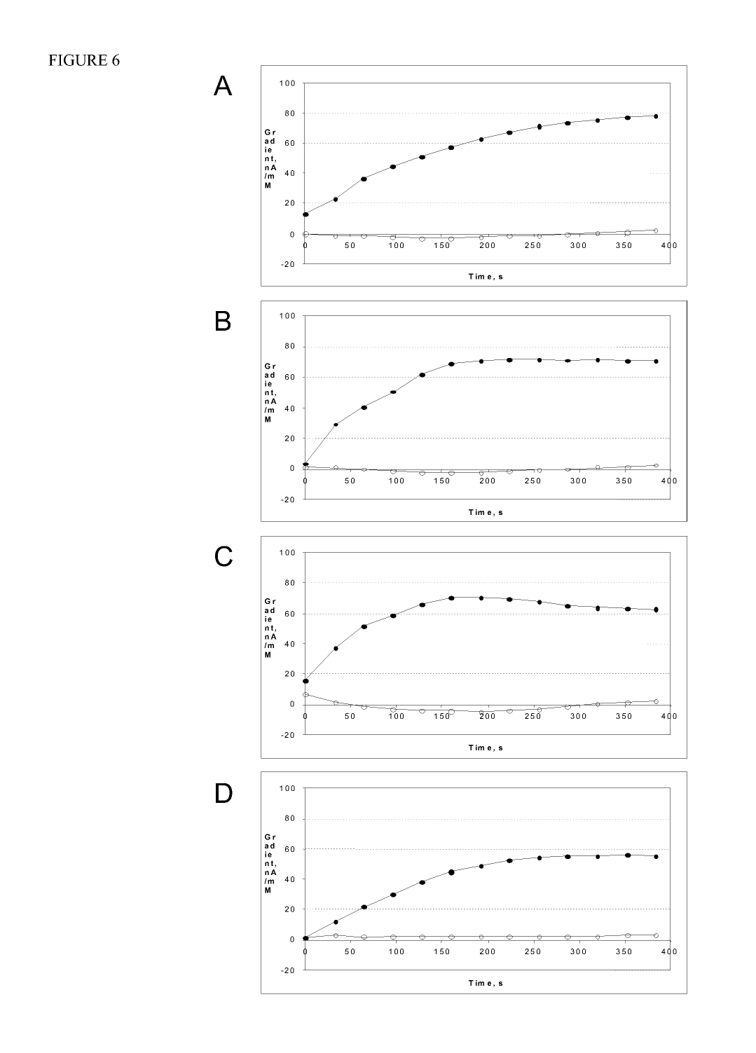

The gradients of response to HDL and LDL versus run time are shown in FIG. 6 for sensors prepared with or without LiCl. Graphs A-D are for sensors containing either no LiCl, 250 mM LiCl, 500 mM LiCl or 750 mM LiCl. HDL and LDL gradients of response are shown with closed and open symbols respectively. The systems are seen to be sensitive to HDL concentration, but not to LDL concentration.

The addition of the inorganic salts was also found to reduce the duration and magnitude of the shoulder on the transient current responses to plasma. The magnitude and duration of the shoulders were again graded 1, 2 or 3 as described in Example 1 and are shown in Table 5.

TABLE 5
Extent of shoulder for enzyme and
chemical entity mixes of Example 3

| Mix | Extent of shoulder |
|---|---|
| 5% SMC no additive | 3 |
| 5% SMC & 250 mM LiCl | 2 |
| 5% SMC & 500 mM LiCl | 2 |
| 5% SMC & 750 mM LiCl | 1 |
| 5% SMC no additive | 3 |
| 5% SMC & 50 mM NaCl | 2 |
| 5% SMC & 500 mM NaCl | 1 |
| 5% SMC & 125 mM CaCl₂ | 2 |
| 5% SMC & 250 mM CaCl₂ | 1 |
| 5% SMC no additive | 3 |
| 5% SMC blank & 280 mM MgCl₂ | 1 |
| 5% SMC no additive | 3 |
| 5% SMC & 15 mM Cr(NH₃)₆Cl₃ | 2 |
| 5% SMC & 60 mM Cr(NH₃)₆Cl₃ | 2 |

### Example 4

The aim of this Example was to investigate the chemical entities of the invention for their ability to improve the electrochemical response of a TC (total cholesterol) sensor with RuAcac redox agent, when using screen printed carbon electrodes and an alternative sugar surfactant.

### Deposition Solution (0.4 μL Aqueous Solution Inserted Per Electrochemical Cell)

0.1 M Tris buffer pH 9.0
10% β-lactose

### 40 mM KOH

### 100 mM Anameg-7

### 40 mM RuAcac

x mM chemical entity or no additive
9 mM thionicotinamide adenine dinucleotide (Oriental Yeast Co)
4.2 mg/ml putidaredoxin reductase (Biocatalysts)
3.4 mg/ml lipase (Genzyme)
22 mg/ml cholesterol dehydrogenase, gelatin free (Amano).

### Chemical Entity

### (i) 500 mM NaCl

(ii) 100 mM neomycin sulphate
(iii) 100 mM streptomycin sulphate
(iv) No additive

Testing Protocol was performed as in Example 1.

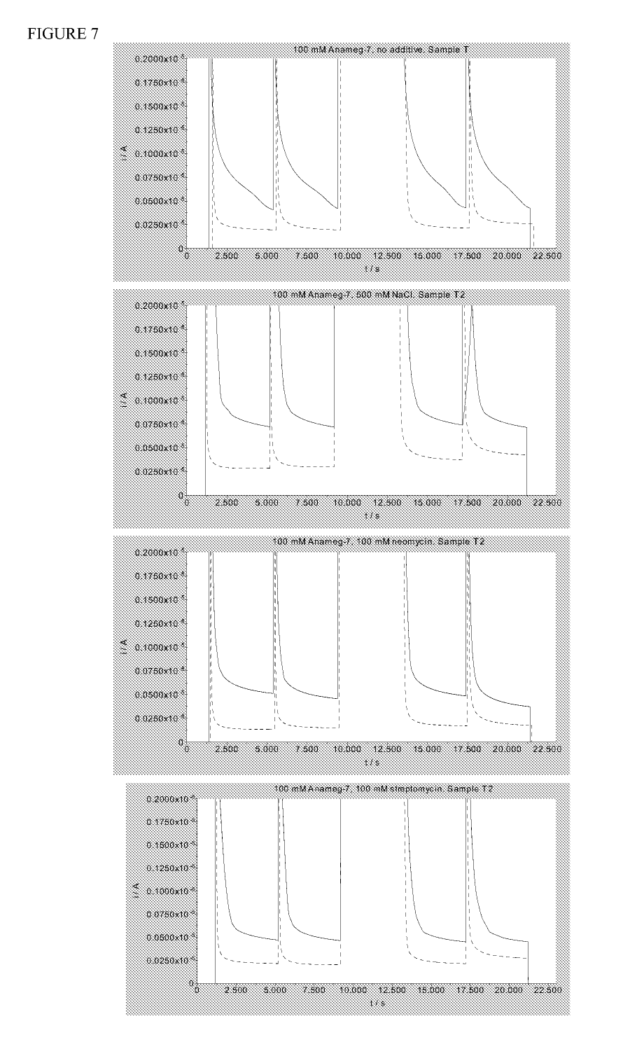

FIG. 7 shows the transient current responses for each of the deposition solutions to samples with TC values of 7.87 mM (no chemical entity additive; plasma sample “T”) or 6.46 mM (all mixes comprising chemical entities; plasma sample “T2”). As in Examples 1 and 2, the data from only the first and last run times are shown for reasons of clarity. The shoulder on the transient response is clearly reduced for sensors comprising enzyme mixes containing any of the chemical entity additives, compared to sensors with enzyme mix containing no additive.

The magnitudes and durations of the shoulders appearing in the current transients were again graded using the “1, 2, 3” criteria. The gradings are shown in Table 6.

TABLE 6
Extent of shoulder for mixes of Example 4

| Mix | Extent of shoulder |
|---|---|
| 5% Anameg no additive | 3 |
| 5% Anameg & NaCl | 1 |
| 5% Anameg & neomycin | 1 |
| 5% Anameg & streptomycin | 1 |

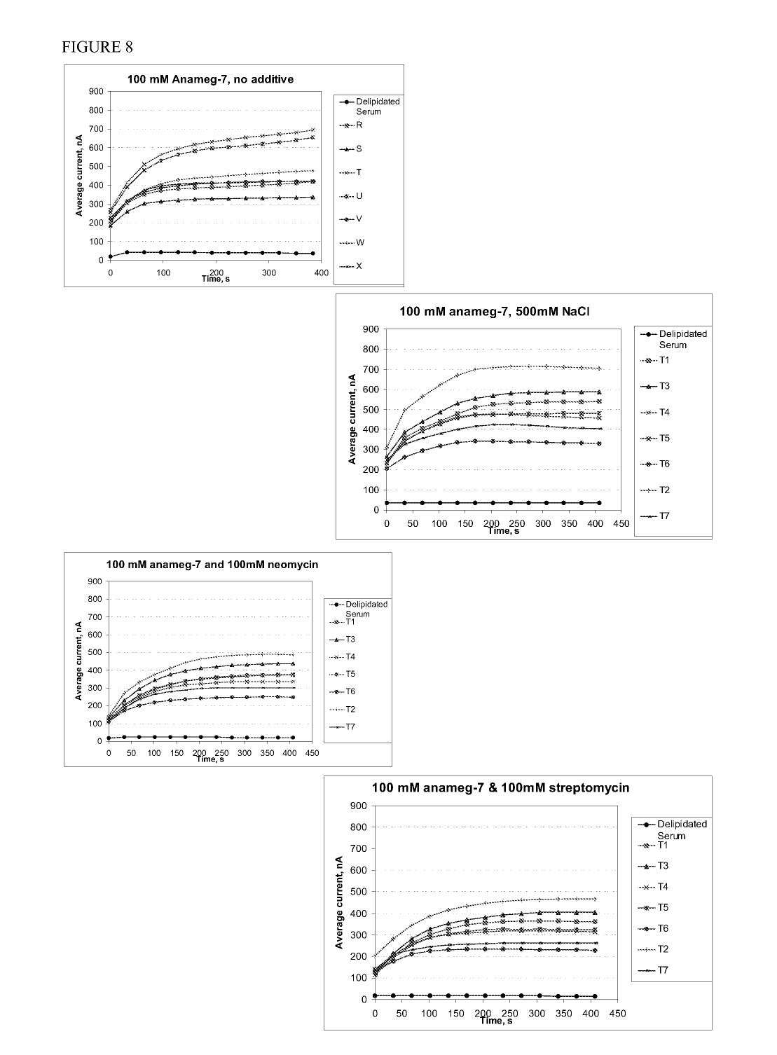

FIG. 8 shows the average current responses as a function of time for various plasma samples.

### Example 5

### Deposition Solution 0.3 μL of Aqueous Solution was Inserted Per Electrochemical Cell

0.1 M iris pH 9.0

### 40 mM KOH

### 40 mM RuAcac

10% w/v lactose.

### 100 mM Anameg-7

8.9 mM Thionicotinamide adenine dinucleotide
4.2 mg/ml Putidaredoxin Reductase
3.3 mg/ml Lipase (Genzyme)
22 mg/ml Cholesterol Dehydrogenase, Gelatin free
X mM chemical entity

### Chemical Entity

### (i) None

### (ii) NaCl (62.5, 125, 250 and 500 mM)

(iii) Neomycin trisulphate (25, 50, 100 or 150 mM)
(iv) spermine.4HCl (25, 50 or 100 mM)

### Plasma Samples

Plasma samples were defrosted for 30 minutes before being centrifuged for 5 minutes at 2900 RCF (Labnet 1618). Delipidated serum (Scipac) was also used as a sample. The samples were analysed using a Konelab clinical analyser for TC concentrations. Three samples were used:
(i) AA (8.58 mM TC),
(ii) AB (3.25 mM TC)
(iii) AC (5.37 mM TC).

### Testing Protocol

20 μL of a plasma samples was used per electrode. On the addition of 20 μl of plasma the chronoamperometry test was initiated. The oxidation current is measured at 0.15 V at 7 time points (0, 56, 112, 168, 224, 280 and 336 seconds), with a reduction current measured at −0.45 V at the final time point (392 seconds). The transient current was measured for 8 seconds, with a data acquisition rate of 100 Hz. Each sample was tested with at least one sensor (four electrochemical cells).

### Results

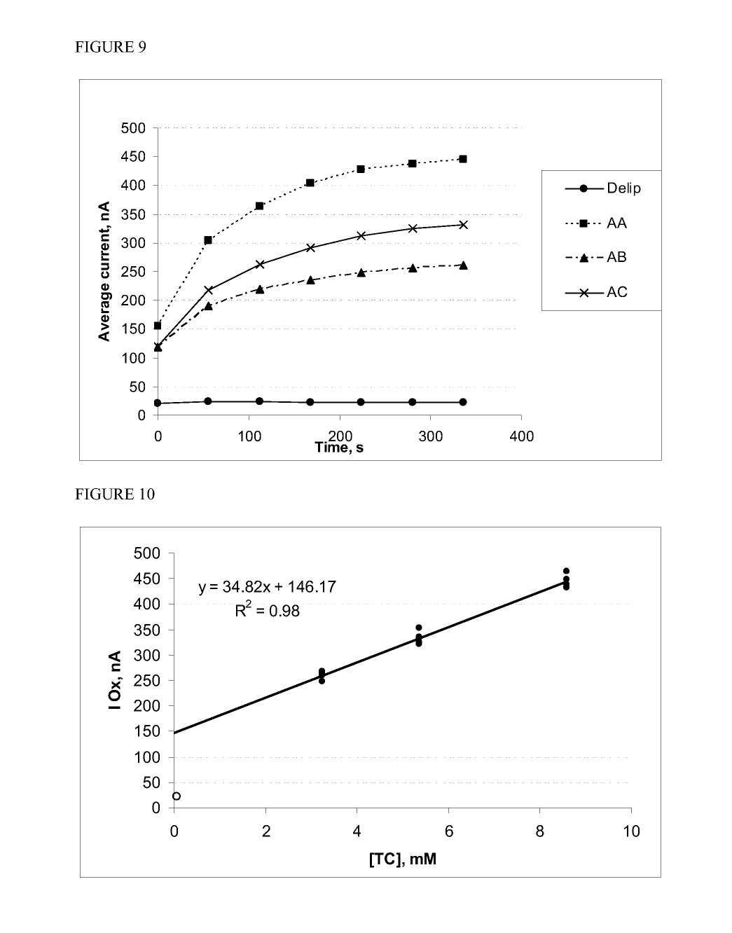

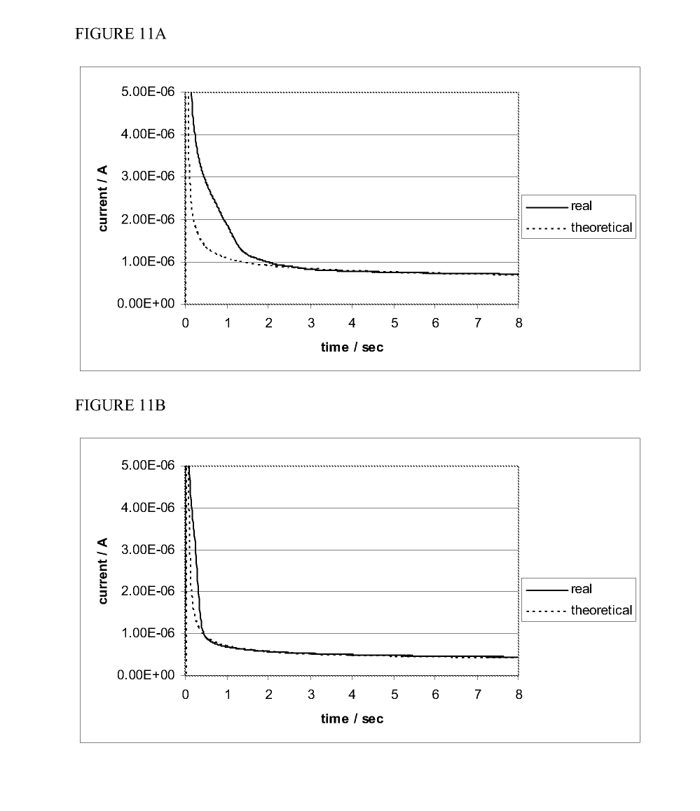

The sensor responses were analyzed to obtain the current values at 8 seconds on the transient current responses. This data was used to plot the average current vs. time for each plasma sample, shown for example in FIG. 9 for sensors containing 150 mM neomycin trisulfate. Current values at the final time point (336 seconds) were used to construct calibration plots of current vs. TC concentration, shown for example in FIG. 10 for sensors containing 150 mM neomycin sulfate.

### Shoulder Analysis

### Method 1:

Each transient current response to plasma samples at the final time point (336 seconds) was analyzed to determine the magnitude of the shoulder on the transient current response. This was done by curve fitting the observed transient response to that predicted by the microband electrode equation for the quasi-steady state response of a microband electrode. Specifically, the equation used was:

$$I = \frac{2 π {AnFD}_{ox} [ Ox ]}{w ln ( 64 \frac{{D}_{ox} t}{{w}^{2}} )} ,$$

where I is the microband current, F is the Faraday constant (96485 C/mol), 4 is the electrode area, n is the number of electrons involved in the electrochemical reaction, Dₒₓ is the diffusion coefficient of the mediator, [Ox] is the concentration of reduced mediator, w is the width of the microband electrode and t is the time.

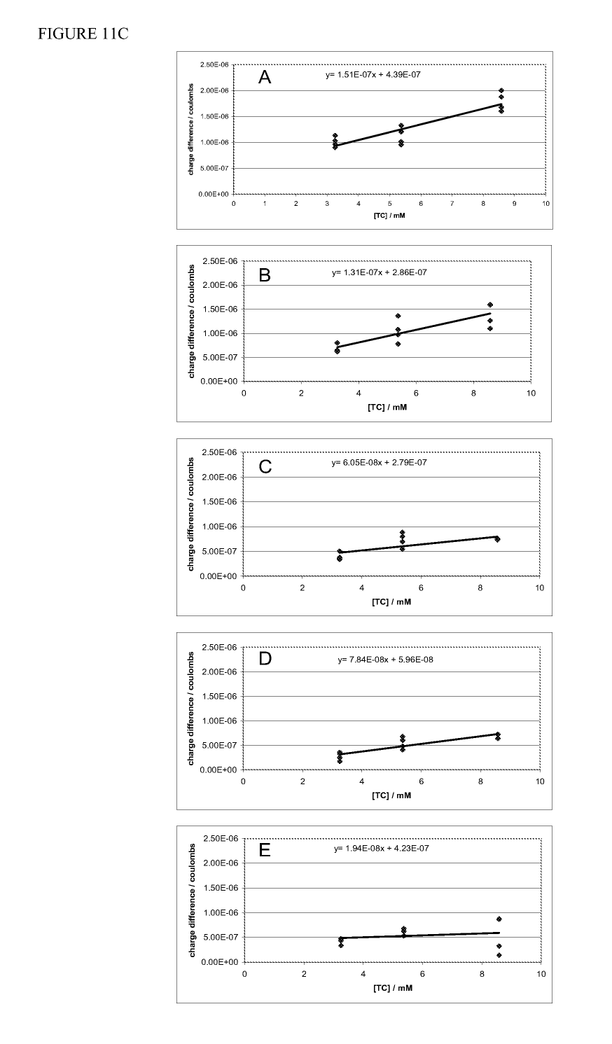

Curve fitting was performed for each transient by varying the value of Dₒₓ to obtain good agreement between the observed and theoretical current values at long times on the transient current response. Two specific examples of this procedure are illustrated in FIG. 11A for the transient response to sample AA using a sensor with no chemical entity additive and in FIG. 11B for the transient response to the same sample, but using a sensor containing 150 mM neomycin sulfate.

The excess charge between the observed response and the theoretical response was calculated using current values between 0.055 and 7.995 seconds on each 8 second transient, according to the equation:

Excess charge (Coulombs)=Σ_{i=0.055}^{i=7.995}0.01(i_{measured}−i_{microband})

This excess charge measure clearly quantifies the shoulder on the transient current response. The magnitude of the shoulder was determined for each of the sensor types with each of the plasma samples, for data at the final time point (336 seconds). The data are given in Table 7 below. Also shown in FIG. 11C are the excess charge measurements obtained at various analyte concentrations when varying quantities of neomycin trisulfate were present in the cell (A is with no additive, and B, C, D and E are with 25, 50, 100 or 150 mM neomycin trisulfate, respectively). This Figure shows clearly that by adding neomycin trisulfate the magnitude of the shoulder can be reduced.

TABLE 7
Extent of shoulder for mixes of Example 5, as
indicated by excess charge of the current transient
relative to microband theory.

| | | Average charge difference in coulombs | | |
|---|---|---|---|---|
| Additive | | Sample AA | Sample AB | Sample AC |
| no additive | | 1.79E−06 | 1.01E−06 | 1.12E−06 |
| 62.5 | mM NaCl | 1.58E−06 | 1.04E−06 | 1.38E−06 |
| 125 | mM NaCl | 1.67E−06 | 8.46E−07 | 1.19E−06 |
| 250 | mM NaCl | 1.59E−06 | 9.59E−07 | 1.07E−06 |
| 500 | mM NaCl | 1.28E−06 | 7.46E−07 | 1.05E−06 |
| 25 | mM Neomycin | 1.39E−06 | 6.77E−07 | 1.05E−06 |
| 50 | mM Neomycin | 7.47E−07 | 3.98E−07 | 7.32E−07 |
| 100 | mM Neomycin | 2.99E−07 | 2.77E−07 | 5.43E−07 |
| 150 | mM Neomycin | 5.52E−07 | 4.28E−07 | 6.29E−07 |
| 25 | mM Spermine | 7.83E−07 | 1.00E−06 | 1.65E−06 |
| 50 | mM Spermine | 6.43E−07 | 8.90E−07 | 1.21E−06 |
| 100 | mM Spermine | 8.27E−07 | 3.62E−07 | 5.95E−07 |

### Method 2:

A grade scale for the magnitude of the shoulder was constructed based on the percentage difference between the observed current value and the theoretical current value at 0.5 second time intervals along the transient current response. A shoulder was assigned a grade of ‘N’, where N is equal to twice the longest time point at which the average difference between the observed and theoretical currents was greater than 10%. A grade of zero would have been assigned if the average percentage difference was less than 10% at the first time point (0.5 seconds). The results for samples AA, AB and AC are shown in Table 8 A.

The current transient reduction current responses to delipidated serum were also analysed for the grade of shoulder according to the method 2 above. The grades of shoulder are given in Table 8B.

TABLE 8A
Extent of shoulder for mixes of Example 5, as indicated by grading system based on
difference between experimental current and microband theory.

| | | Sample AA | | | | | |
|---|---|---|---|---|---|---|---|
| | | % difference in | | Sample AB | | Sample AC | |
| | time/ | (i_{obs} − iₜₕₑₒ) | | % difference in (i_{obs} − | | % difference in | |
| Additive | sec | average | N | iₜₕₑₒ) average | N | (i_{obs} − iₜₕₑₒ) average | N |
| No | 0.5 | 112.82 | 3 | 132.89 | 3 | 111.32 | 3 |
| additive | 1.0 | 54.72 | | 47.44 | | 34.94 | |
| | 1.5 | 16.82 | | 17.85 | | 10.57 | |
| | 2.0 | 6.47 | | 9.76 | | 2.79 | |
| | 2.5 | 3.59 | | 4.27 | | 0.26 | |
| | 3.0 | 0.38 | | 2.33 | | −0.22 | |
| | 3.5 | 0.13 | | 0.98 | | 0.33 | |
| | 4.0 | 0.70 | | 1.36 | | 0.78 | |
| 62.5 mM | 0.5 | 114.54 | 2 | 163.04 | 1 | 151.46 | 2 |
| NaCl | 1.0 | 50.68 | | 3.81 | | 17.38 | |
| | 1.5 | −1.66 | | 0.37 | | 0.16 | |
| | 2.0 | −3.82 | | 0.54 | | −0.15 | |
| | 2.5 | −3.02 | | 0.97 | | 0.55 | |
| | 3.0 | −2.15 | | 1.45 | | 1.26 | |
| | 3.5 | −1.35 | | 1.92 | | 1.93 | |
| | 4.0 | −0.60 | | 2.40 | | 2.59 | |
| 125 mM | 0.5 | 141.07 | 2 | 99.21 | 1 | 130.70 | 2 |
| NaCl | 1.0 | 20.61 | | 2.71 | | 10.43 | |
| | 1.5 | 1.76 | | 1.14 | | −0.01 | |
| | 2.0 | 0.77 | | 1.76 | | 0.30 | |
| | 2.5 | 1.79 | | 2.41 | | 1.14 | |
| | 3.0 | 2.71 | | 3.01 | | 1.96 | |
| | 3.5 | 3.56 | | 3.60 | | 2.72 | |
| | 4.0 | 4.34 | | 4.16 | | 3.40 | |
| 250 mM | 0.5 | 131.61 | 4 | 68.24 | 3 | 65.82 | 1 |
| NaCl | 1.0 | 42.00 | | 20.23 | | 6.72 | |
| | 1.5 | 22.14 | | 14.57 | | 1.51 | |
| | 2.0 | 12.33 | | 8.83 | | 0.49 | |
| | 2.5 | 6.76 | | 4.94 | | 0.54 | |
| | 3.0 | 1.27 | | 4.59 | | 1.31 | |
| | 3.5 | 0.12 | | 3.84 | | 2.02 | |
| | 4.0 | 0.73 | | 3.97 | | 2.64 | |
| 500 mM | 0.5 | 36.22 | 1 | 44.22 | 1 | 11.14 | 1 |
| NaCl | 1.0 | 7.00 | | 4.34 | | −2.96 | |
| | 1.5 | −0.66 | | 1.88 | | −1.57 | |
| | 2.0 | 0.47 | | 2.54 | | −0.34 | |
| | 2.5 | 1.47 | | 3.23 | | 0.68 | |
| | 3.0 | 2.35 | | 3.89 | | 1.58 | |
| | 3.5 | 3.15 | | 4.50 | | 2.40 | |
| | 4.0 | 3.87 | | 5.05 | | 3.16 | |
| 25 mM | 0.5 | 86.51 | 5 | 75.32 | 2 | 77.64 | 4 |
| Neomycin | 1.0 | 34.08 | | 14.04 | | 35.19 | |
| | 1.5 | 21.06 | | 2.79 | | 20.44 | |
| | 2.0 | 14.27 | | −0.45 | | 13.58 | |
| | 2.5 | 10.47 | | −2.05 | | 9.37 | |
| | 3.0 | 7.57 | | −1.74 | | 5.05 | |
| | 3.5 | 5.10 | | −1.31 | | 3.06 | |
| | 4.0 | 3.14 | | −0.91 | | 0.64 | |
| 50 mM | 0.5 | 31.28 | 1 | 11.06 | 1 | 25.02 | 1 |
| Neomycin | 1.0 | 6.75 | | 0.35 | | 5.88 | |
| | 1.5 | 5.63 | | 0.29 | | 0.62 | |
| | 2.0 | 3.90 | | 1.01 | | 1.51 | |
| | 2.5 | 3.10 | | 1.71 | | 2.23 | |
| | 3.0 | 3.96 | | 2.34 | | 2.91 | |
| | 3.5 | 4.69 | | 2.97 | | 3.51 | |
| | 4.0 | 5.36 | | 3.53 | | 4.03 | |
| 100 mM | 0.5 | 4.18 | 0 | 0.76 | 0 | 3.71 | 0 |
| Neomycin | 1.0 | 0.87 | | 0.73 | | 3.43 | |
| | 1.5 | 0.89 | | 1.46 | | 5.88 | |
| | 2.0 | 2.86 | | 1.55 | | 7.53 | |
| | 2.5 | 3.90 | | 2.31 | | 8.85 | |
| | 3.0 | 4.76 | | 2.95 | | 9.94 | |
| | 3.5 | 5.92 | | 3.56 | | 10.88 | |
| | 4.0 | 6.92 | | 4.10 | | 11.73 | |
| 150 mM | 0.5 | 24.34 | 1 | 2.10 | 0 | 0.55 | 0 |
| Neomycin | 1.0 | 2.42 | | 0.51 | | 2.72 | |
| | 1.5 | 1.59 | | 1.07 | | 4.13 | |
| | 2.0 | 1.78 | | 1.69 | | 4.99 | |
| | 2.5 | 2.73 | | 2.28 | | 5.74 | |
| | 3.0 | 3.66 | | 2.84 | | 6.36 | |
| | 3.5 | 4.48 | | 3.36 | | 6.88 | |
| | 4.0 | 5.25 | | 3.86 | | 7.35 | |
| 25 mM | 0.5 | 123.19 | 2 | 68.15 | 1 | 95.05 | 1 |
| Spermine | 1.0 | 29.91 | | 0.21 | | 6.14 | |
| | 1.5 | 8.63 | | −0.36 | | 0.26 | |
| | 2.0 | 4.00 | | −0.19 | | 0.06 | |
| | 2.5 | 3.43 | | 0.12 | | 0.40 | |
| | 3.0 | 2.47 | | 0.46 | | 0.84 | |
| | 3.5 | 1.88 | | 0.80 | | 1.26 | |
| | 4.0 | 2.34 | | 1.15 | | 1.64 | |
| 50 mM | 0.5 | 62.81 | 1 | 26.61 | 1 | 43.68 | 1 |
| Spermine | 1.0 | −0.43 | | −0.16 | | −0.57 | |
| | 1.5 | 0.83 | | −0.33 | | 0.29 | |
| | 2.0 | 1.93 | | −0.06 | | 1.06 | |
| | 2.5 | 2.85 | | 0.31 | | 1.70 | |
| | 3.0 | 3.63 | | 0.70 | | 2.24 | |
| | 3.5 | 4.32 | | 1.14 | | 2.74 | |
| | 4.0 | 4.98 | | 1.60 | | 3.20 | |
| 100 mM | 0.5 | 7.00 | 0 | 0.95 | 0 | −0.15 | 0 |
| Spermine | 1.0 | 3.75 | | −0.13 | | 1.92 | |
| | 1.5 | 4.22 | | 0.60 | | 3.29 | |
| | 2.0 | 4.97 | | 1.26 | | 4.13 | |
| | 2.5 | 5.74 | | 1.87 | | 4.85 | |
| | 3.0 | 6.26 | | 2.44 | | 5.45 | |
| | 3.5 | 7.00 | | 2.97 | | 5.96 | |
| | 4.0 | 7.09 | | 3.48 | | 6.42 | |

TABLE 8B
Extent of shoulder for delipidated reduction current
transients of Example 5, as indicated by grading system
based on difference between experimental current and
microband theory.

| Additive | Grade of shoulder |
|---|---|
| No additive | 4 |

| | | |
|---|---|---|
| 62.5 | mM NaCl | 3 |
| 125 | mM NaCl | 2 |
| 250 | mM NaCl | 2 |
| 500 | mM NaCl | 1 |
| 25 | mM Neomycin | 3 |
| 50 | mM Neomycin | 1 |
| 100 | mM Neomycin | 1 |
| 150 | mM Neomycin | 1 |
| 25 | mM Spermine | 2 |
| 50 | mM Spermine | 1 |
| 100 | mM Spermine | 1 |

### Example 6

### Deposition Solution (0.3 μL of Aqueous Solution was Inserted Per Electrochemical Cell)

### 0.1 M Tris pH 9.0

### 30 mM KOH

### 30 mM RuAcac

10% w/v lactose.
5% sucrose monocaprate (SMC)
8.9 mM thionicotinamide adenine dinucleotide
4.2 mg/ml putidaredoxin reductase
3.3 mg/ml lipase (Genzyme)
22 mg/ml cholesterol dehydrogenase, gelatin free
X mM chemical entity

### Chemical Entity

### (i) None

(ii) 150 mM Neomycin trisulphate
(iii) 25 mM Spermine.4HCl

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Konelab clinical analyser for high density cholesterol (HDL) concentrations. Seven samples were used:
(i) BA (1.45 mM HDL)
(ii) BB (3.05 mM HDL)
(iii) BC (2.86 mM HDL)
(iv) BD (5.0 mM HDL)
(v) BE (2.4 mM HDL)
(vi) BF (1.88 mM HDL)
(vii) BG (1.26 mM HDL)

### Testing Protocol

20 μL of a plasma samples was used per electrode. On the addition of 20 μl of plasma the chronoamperometry test was initiated. The oxidation current is measured at 0.15 V at 7 time points (0, 56, 112, 168, 224, 280 and 336 seconds), with a reduction current measured at −0.45 V at the final time point (392). The transient current was measured for 8 seconds, with a data acquisition rate of 100 Hz. Each sample was tested with at least one sensor (i.e., four electrochemical cells or “wells”).

### Results

The sensor responses were analyzed to obtain the current values at 8 seconds on the transient current responses, which were then used to construct calibration plots of current vs. HDL concentration at each time point.

### Shoulder Analysis

Each transient current response at the final time point was analyzed to determine the magnitude of the shoulder on the transient current response, by curve fitting to microband theory as described in Example 5.

The reduction of the excess charge due to the shoulder on the transient current response by the chemical entity additives is demonstrated in Table 9, using data at the final time point (336 seconds).

TABLE 9
Extent of shoulder for mixes of Example 6, as indicated by excess
charge of the current transient relative to microband theory.

| | charge difference/coulombs | | | | | |
|---|---|---|---|---|---|---|
| | well 1 | well 2 | well 3 | well 4 | average | st dev |
| Sample BG | | | | | | |
| No additive | 9.34E−07 | 1.01E−06 | 9.87E−07 | 1.15E−06 | 1.02E−06 | 9.02E−08 |
| 150 mM Neomycin | 1.13E−06 | 1.34E−06 | 1.75E−06 | 2.12E−06 | 1.59E−06 | 4.41E−07 |
| 25 mM Spermine | 4.95E−07 | 4.68E−07 | 5.78E−07 | 6.88E−07 | 5.57E−07 | 9.88E−08 |
| Sample BA | | | | | | |
| No additive | 8.42E−07 | 8.83E−07 | 1.04E−06 | 9.77E−07 | 9.35E−07 | 9.00E−08 |
| 150 mM Neomycin | 8.41E−07 | 6.34E−07 | 6.45E−07 | 6.15E−07 | 6.84E−07 | 1.06E−07 |
| 25 mM Spermine | 7.43E−07 | 5.49E−07 | 8.25E−07 | 6.42E−07 | 6.90E−07 | 1.20E−07 |
| Sample BF | | | | | | |
| No additive | 1.07E−06 | 8.06E−07 | 1.18E−06 | 1.21E−06 | 1.07E−06 | 1.85E−07 |
| 150 mM Neomycin | 7.23E−07 | 5.04E−07 | 7.93E−07 | 6.69E−07 | 6.72E−07 | 1.23E−07 |
| 25 mM Spermine | 5.05E−07 | 7.20E−07 | 5.99E−07 | 6.14E−07 | 6.09E−07 | 8.81E−08 |
| Sample BE | | | | | | |
| No additive | 9.95E−07 | 1.10E−06 | 1.27E−06 | 1.29E−06 | 1.16E−06 | 1.40E−07 |
| 150 mM Neomycin | 7.67E−07 | 8.79E−07 | 9.95E−07 | 7.25E−07 | 8.42E−07 | 1.21E−07 |
| 25 mM Spermine | 7.71E−07 | | 8.19E−07 | 8.18E−07 | 8.02E−07 | 2.73E−08 |
| Sample BC | | | | | | |
| No additive | 1.48E−06 | 1.44E−06 | 1.69E−06 | 1.89E−06 | 1.63E−06 | 2.06E−07 |
| 150 mM Neomycin | 7.22E−07 | 7.61E−07 | 9.91E−07 | 1.13E−06 | 9.00E−07 | 1.92E−07 |
| 25 mM Spermine | 9.07E−07 | 9.18E−07 | 9.18E−07 | 1.09E−06 | 9.59E−07 | 8.85E−08 |
| Sample BB | | | | | | |
| No additive | 1.07E−06 | 1.31E−06 | 1.57E−06 | 1.60E−06 | 1.39E−06 | 2.51E−07 |
| 150 mM Neomycin | 9.91E−07 | 9.50E−07 | 8.35E−07 | 8.09E−07 | 8.96E−07 | 8.82E−08 |
| 25 mM Spermine | 9.10E−07 | 1.16E−06 | 1.31E−06 | 1.15E−06 | 1.13E−06 | 1.66E−07 |
| Sample BD | | | | | | |
| No additive | 1.99E−06 | 2.23E−06 | 2.32E−06 | 2.43E−06 | 2.24E−06 | 1.85E−07 |
| 150 mM Neomycin | 2.06E−06 | 1.04E−06 | 1.56E−06 | 1.86E−06 | 1.63E−06 | 4.43E−07 |
| 25 mM Spermine | 9.71E−07 | 7.44E−07 | 1.08E−06 | 1.08E−06 | 9.69E−07 | 1.59E−07 |

The grade “N” of the shoulders were also determined, as described in Example 6. The results are shown in Table 10.

TABLE 10
Extent of shoulder for mixes of Example 6, as indicated by grading system based
on difference between experimental current and microband theory.

| | | % difference | | | | | | | | | |
|---|---|---|---|---|---|---|---|---|---|---|---|
| | time/ | in (i_{obs} − | grade of | | time/ | % difference | grade of | | time/ | % difference | grade of |
| | sec | iₜₕₑₒ) | shoulder | | sec | in (i_{obs} − iₜₕₑₒ) | shoulder | | sec | in (i_{obs} − iₜₕₑₒ) | shoulder |
| No | 0.5 | 213.6 | 5 | 150 mM | 0.5 | 245.6 | 4 | 25 mM | 0.5 | 118.7 | 2 |
| additive | 1 | 134.1 | | Neomycin | 1 | 159.8 | | Spermine | 1 | 23.8 | |
| Sample | 1.5 | 82.4 | | Sample | 1.5 | 69.8 | | Sample | 1.5 | 5.3 | |
| BG | 2 | 41.7 | | BG | 2 | 21.6 | | BG | 2 | 1.1 | |
| | 2.5 | 17.5 | | | 2.5 | 6.1 | | | 2.5 | 0.2 | |
| | 3 | 9.0 | | | 3 | 1.4 | | | 3 | −0.4 | |
| | 3.5 | 5.6 | | | 3.5 | 0.9 | | | 3.5 | −0.9 | |
| | 4 | 3.9 | | | 4 | 0.8 | | | 4 | −1.7 | |
| | time/ | | grade of | | time/ | | grade of | | time/ | | grade of |
| | sec | average | shoulder | | sec | average | shoulder | | sec | average | shoulder |
| No | 0.5 | 219.0 | 5 | 150 mM | 0.5 | 259.4 | 2 | 25 mM | 0.5 | 243.4 | 2 |
| additive | 1 | 142.7 | | Neomycin | 1 | 42.8 | | Spermine | 1 | 39.0 | |
| Sample | 1.5 | 91.9 | | Sample | 1.5 | 3.2 | | Sample | 1.5 | 3.8 | |
| BA | 2 | 39.4 | | BA | 2 | 1.2 | | BA | 2 | 1.5 | |
| | 2.5 | 12.0 | | | 2.5 | 0.9 | | | 2.5 | 1.2 | |
| | 3 | 5.3 | | | 3 | 0.9 | | | 3 | 1.1 | |
| | 3.5 | 2.9 | | | 3.5 | 1.1 | | | 3.5 | 1.1 | |
| | 4 | 1.8 | | | 4 | 1.4 | | | 4 | 1.4 | |
| No | 0.5 | 204.4 | 6 | 150 mM | 0.5 | 229.8 | 2 | 25 mM | 0.5 | 155.7 | 3 |
| additive | 1 | 138.5 | | Neomycin | 1 | 36.7 | | Spermine | 1 | 49.7 | |
| Sample | 1.5 | 92.7 | | Sample | 1.5 | 3.2 | | Sample | 1.5 | 17.2 | |
| BF | 2 | 55.2 | | BF | 2 | 1.5 | | BF | 2 | 5.2 | |
| | 2.5 | 27.4 | | | 2.5 | 1.6 | | | 2.5 | 0.6 | |
| | 3 | 10.9 | | | 3 | 1.8 | | | 3 | −0.4 | |
| | 3.5 | 5.3 | | | 3.5 | 2.1 | | | 3.5 | −1.3 | |
| | 4 | 3.1 | | | 4 | 2.6 | | | 4 | −1.0 | |
| No | 0.5 | 173.8 | 5 | 150 mM | 0.5 | 239.1 | 2 | 25 mM | 0.5 | 127.6 | 2 |
| additive | 1 | 115.2 | | Neomycin | 1 | 65.6 | | Spermine | 1 | 22.1 | |
| Sample | 1.5 | 75.0 | | Sample | 1.5 | 8.6 | | Sample | 1.5 | −3.3 | |
| BE | 2 | 42.9 | | BE | 2 | 1.1 | | BE | 2 | −12.3 | |
| | 2.5 | 19.5 | | | 2.5 | −0.4 | | | 2.5 | −14.8 | |
| | 3 | 8.4 | | | 3 | −0.3 | | | 3 | −15.8 | |
| | 3.5 | 4.2 | | | 3.5 | 0.0 | | | 3.5 | −16.6 | |
| | 4 | 2.3 | | | 4 | 0.4 | | | 4 | −16.4 | |
| No | 0.5 | 182.3 | 6 | 150 mM | 0.5 | 203.0 | 3 | 25 mM | 0.5 | 160.6 | 2 |
| additive | 1 | 141.1 | | Neomycin | 1 | 92.8 | | Spermine | 1 | 47.6 | |
| Sample | 1.5 | 107.2 | | Sample | 1.5 | 20.2 | | Sample | 1.5 | 8.5 | |
| BC | 2 | 80.5 | | BC | 2 | 2.4 | | BC | 2 | 1.9 | |
| | 2.5 | 55.7 | | | 2.5 | −0.2 | | | 2.5 | 0.0 | |
| | 3 | 24.1 | | | 3 | 0.2 | | | 3 | 0.1 | |
| | 3.5 | 7.0 | | | 3.5 | 0.7 | | | 3.5 | 0.3 | |
| | 4 | 2.6 | | | 4 | 1.3 | | | 4 | 0.7 | |
| No | 0.5 | 170.8 | 6 | 150 mM | 0.5 | 202.9 | 2 | 25 mM | 0.5 | 170.1 | 4 |
| additive | 1 | 120.5 | | Neomycin | 1 | 75.7 | | Spermine | 1 | 81.7 | |
| Sample | 1.5 | 84.5 | | Sample | 1.5 | 7.4 | | Sample | 1.5 | 35.8 | |
| [symbol] | 2 | 56.6 | | [symbol] | 2 | −0.5 | | [symbol] | 2 | 17.3 | |
| | 2.5 | 31.0 | | | 2.5 | −0.4 | | | 2.5 | 9.5 | |
| | 3 | 12.0 | | | 3 | 0.4 | | | 3 | 6.3 | |
| | 3.5 | 4.7 | | | 3.5 | 1.1 | | | 3.5 | 4.8 | |
| | 4 | 2.4 | | | 4 | 1.9 | | | 4 | 4.3 | |
| No | 0.5 | 139.9 | 8 | 150 mM | 0.5 | 178.1 | 4 | 25 mM | 0.5 | 114.0 | 3 |
| additive | 1 | 112.4 | | Neomycin | 1 | 132.5 | | Spermine | 1 | 42.0 | |
| Sample | 1.5 | 88.3 | | Sample | 1.5 | 58.8 | | Sample | 1.5 | 12.7 | |
| BD | 2 | 69.3 | | BD | 2 | 16.5 | | BD | 2 | 7.1 | |
| | 2.5 | 54.5 | | | 2.5 | 3.5 | | | 2.5 | 4.0 | |
| | 3 | 42.0 | | | 3 | 0.3 | | | 3 | 3.0 | |
| | 3.5 | 29.0 | | | 3.5 | 0.8 | | | 3.5 | 1.7 | |
| | 4 | 15.5 | | | 4 | 1.6 | | | 4 | 0.2 | |

[symbol]

indicates data missing or illegible when filed

### Example 7

### Deposition Solution (0.4 Ml of Aqueous Solution was Inserted Per Electrochemical Cell)

### 0.1 M Tris (pH 9.0)

### 30 mM KOH

### 30 mM RuAcac

10% w/v lactose
8.9 mM thionicotinamide adenine dinucleotide
4.2 mg/ml putidaredoxin reductase.
3.3 mg/ml lipase (Genzyme)
22 mg/ml cholesterol dehydrogenase, gelatin free
No chemical entity
100 mM sugar surfactant, as defined below.

### Sugar Surfactant

(i) None
(ii) Cymal 2
(iii) Cymal 3
(iv) Cymal 4
(v) Cymal 5
(vi) Cymal 6
(vii) Cymal 7
(viii) Anameg 7
(ix) Cyglu 3
(x) C-Hega 9
(xi) C-Hega 10
(xii) C-Hega 11
(xiii) Hega 8
(xiv) Hega 9
(xv) Mega 7
(xvi) Mega 8
(xvii) n-decyl-β-D-maltopyranoside
(xviii) n-dodecyl-β-D-maltopyranoside
(xix) n-undecyl-β-D-maltopyranoside
(xx) n-hexyl-β-D-glucopyranoside
(xxi) n-heptyl-β-D-glucopyranoside
(xxii) n-octyl-β-D-glucopyranoside
(xxiii) n-octanoyl sucrose
(xxiv) n-dodecanyol sucrose
(xxv) sucrose monocaprate

The dispensed sensor sheets were then placed into a LS40 freeze drier (Severn Science) for freeze drying.

### Test Samples

The following test samples were prepared in delipdated serum (Scipac):
(i) 0 mM NADH
(ii) 2.5 mM NADH
(iii) 5.0 mM NADH
(iv) 7.5 mM NADH

### Testing Protocol

20 μL of a plasma samples was used per electrode. On the addition of 20 μl of plasma the chronoamperometry test was initiated. The oxidation current was measured at 0.15 Vat 5 time points (0, 56, 112, 168 and 224 seconds), with a reduction current measured at −0.45 V at the final time point (280). The transient current was measured for 8 seconds, with a data acquisition rate of 100 Hz. Each sample was tested with at least one sensor (four electrochemical cells).

### Results

The sensor responses were analyzed to obtain the current values at 8 seconds on the transient current responses, which were then used to construct calibration plots of current vs. NADH concentration at each time point.

### Shoulder Analysis

Each transient current response to 7.5 mM NADH at the final time point (224 seconds) was also analyzed to determine the magnitude of the shoulder on the transient current response, by curve fitting and determining the grade of the shoulder, as described in Example 5. The grades of the shoulders are given in Table 11.

TABLE 11
Extent of shoulder for mixes of Example 7, as indicated by
grading system based on difference between experimental
current and microband theory.

| | | % difference in (i_{obs} − iₜₕₑₒ) | grade of |
|---|---|---|---|
| | time/sec | average | shoulder |
| 100 mM cymal-2 | 0.5 | 86.7 | 11 |
| | 1 | 86.9 | |
| | 1.5 | 85.0 | |
| | 2 | 81.3 | |
| | 2.5 | 75.5 | |
| | 3 | 66.7 | |
| | 3.5 | 57.2 | |
| | 4 | 45.9 | |
| | 4.5 | 35.8 | |
| | 5 | 25.6 | |
| | 5.5 | 16.6 | |
| | 6 | 8.4 | |
| 100 mM cymal-3 | 0.5 | 83.4 | 12 |
| | 1 | 79.1 | |
| | 1.5 | 75.5 | |
| | 2 | 71.9 | |
| | 2.5 | 68.2 | |
| | 3 | 63.3 | |
| | 3.5 | 56.5 | |
| | 4 | 48.9 | |
| | 4.5 | 40.7 | |
| | 5 | 30.0 | |
| | 5.5 | 19.3 | |
| | 6 | 10.2 | |
| 100 mM cymal-4 | 0.5 | 88.2 | 12 |
| | 1 | 83.8 | |
| | 1.5 | 80.3 | |
| | 2 | 76.1 | |
| | 2.5 | 71.9 | |
| | 3 | 66.4 | |
| | 3.5 | 59.4 | |
| | 4 | 51.2 | |
| | 4.5 | 42.2 | |
| | 5 | 31.1 | |
| | 5.5 | 20.2 | |
| | 6 | 10.6 | |
| 100 mM cymal-5 | 0.5 | 92.3 | 10 |
| | 1 | 90.5 | |
| | 1.5 | 86.6 | |
| | 2 | 81.0 | |
| | 2.5 | 71.2 | |
| | 3 | 59.3 | |
| | 3.5 | 45.1 | |
| | 4 | 29.1 | |
| | 4.5 | 18.7 | |
| | 5 | 13.4 | |
| 100 mM cymal-6 | 0.5 | 107.6 | 8 |
| | 1 | 99.7 | |
| | 1.5 | 87.1 | |
| | 2 | 70.3 | |
| | 2.5 | 50.9 | |
| | 3 | 33.8 | |
| | 3.5 | 21.3 | |
| | 4 | 10.9 | |
| 100 mM cymal-7 | 0.5 | 105.1 | 5 |
| | 1 | 88.9 | |
| | 1.5 | 59.9 | |
| | 2 | 33.7 | |
| | 2.5 | 16.2 | |
| | 3 | 6.2 | |
| | 3.5 | 1.6 | |
| | 4 | −0.3 | |
| 100 mM Anameg-7 | 0.5 | 108.5 | 9 |
| | 1 | 109.5 | |
| | 1.5 | 102.7 | |
| | 2 | 88.6 | |
| | 2.5 | 75.9 | |
| | 3 | 58.5 | |
| | 3.5 | 41.3 | |
| | 4 | 25.4 | |
| | 4.5 | 11.3 | |
| | 5 | 6.8 | |
| 100 mM Cyglu-3 | 0.5 | 125.9 | 7 |
| | 1 | 120.9 | |
| | 1.5 | 109.1 | |
| | 2 | 87.0 | |
| | 2.5 | 57.3 | |
| | 3 | 34.1 | |
| | 3.5 | 18.9 | |
| | 4 | 9.7 | |
| 100 mM C-HEGA-9 | 0.5 | 13.3 | 2 |
| | 1 | 10.1 | |
| | 1.5 | 5.5 | |
| | 2 | 2.7 | |
| | 2.5 | 0.5 | |
| | 3 | −0.3 | |
| | 3.5 | −0.6 | |
| | 4 | −0.7 | |
| 100 mM C-HEGA-10 | 0.5 | 101.3 | 6 |
| | 1 | 89.9 | |
| | 1.5 | 68.0 | |
| | 2 | 46.8 | |
| | 2.5 | 28.7 | |
| | 3 | 15.8 | |
| | 3.5 | 7.6 | |
| | 4 | 2.0 | |
| 100 mM C-HEGA-11 | 0.5 | 92.8 | 4 |
| | 1 | 68.5 | |
| | 1.5 | 43.2 | |
| | 2 | 20.2 | |
| | 2.5 | 9.0 | |
| | 3 | 2.7 | |
| | 3.5 | 0.2 | |
| | 4 | −0.5 | |
| 100 mM HEGA-8 | 0.5 | 52.8 | 5 |
| | 1 | 39.9 | |
| | 1.5 | 28.0 | |
| | 2 | 21.0 | |
| | 2.5 | 14.2 | |
| | 3 | 9.7 | |
| | 3.5 | 7.0 | |
| | 4 | 4.3 | |
| 100 mM HEGA-9 | 0.5 | 94.0 | 11 |
| | 1 | 89.1 | |
| | 1.5 | 86.2 | |
| | 2 | 83.5 | |
| | 2.5 | 80.1 | |
| | 3 | 75.0 | |
| | 3.5 | 67.5 | |
| | 4 | 57.3 | |
| | 4.5 | 43.2 | |
| | 5 | 28.1 | |
| | 5.5 | 16.6 | |
| | 6 | 9.0 | |
| 100 mM MEGA-7 | 0.5 | 8.4 | 3 |
| | 1 | 10.5 | |
| | 1.5 | 10.4 | |
| | 2 | 9.3 | |
| | 2.5 | 7.8 | |
| | 3 | 5.9 | |
| | 3.5 | 4.2 | |
| | 4 | 3.2 | |
| 100 mM MEGA-8 | 0.5 | 94.7 | 10 |
| | 1 | 93.9 | |
| | 1.5 | 92.0 | |
| | 2 | 88.8 | |
| | 2.5 | 83.4 | |
| | 3 | 74.0 | |
| | 3.5 | 58.4 | |
| | 4 | 42.0 | |
| | 4.5 | 27.1 | |
| | 5 | 12.6 | |
| 100 mM n-decyl-b-D- | 0.5 | 89.1 | 10 |
| maltoside | 1 | 84.4 | |
| | 1.5 | 75.4 | |
| | 2 | 64.0 | |
| | 2.5 | 53.5 | |
| | 3 | 43.5 | |
| | 3.5 | 34.1 | |
| | 4 | 24.5 | |
| | 4.5 | 17.0 | |
| | 5 | 10.0 | |
| 100 mM n-undecyl-b- | 0.5 | 92.1 | 7 |
| D-maltoside | 1 | 76.3 | |
| | 1.5 | 53.4 | |
| | 2 | 36.8 | |
| | 2.5 | 25.9 | |
| | 3 | 17.0 | |
| | 3.5 | 11.4 | |
| | 4 | 8.3 | |
| 100 mM n-dodecyl-b- | 0.5 | 106.3 | 5 |
| D-maltoside | 1 | 88.7 | |
| | 1.5 | 55.1 | |
| | 2 | 32.6 | |
| | 2.5 | 16.7 | |
| | 3 | 6.3 | |
| | 3.5 | 2.2 | |
| | 4 | 0.0 | |
| 100 mM n-hexyl-b-D- | 0.5 | 13.8 | 5 |
| glucoside | 1 | 14.0 | |
| | 1.5 | 13.4 | |
| | 2 | 12.0 | |
| | 2.5 | 10.3 | |
| | 3 | 8.4 | |
| | 3.5 | 6.2 | |
| | 4 | 4.3 | |
| 100 mM n-heptyl-b- | 0.5 | 100.9 | 10 |
| D-glucoside | 1 | 100.0 | |
| | 1.5 | 95.9 | |
| | 2 | 85.1 | |
| | 2.5 | 64.6 | |
| | 3 | 50.5 | |
| | 3.5 | 35.9 | |
| | 4 | 26.4 | |
| | 4.5 | 19.1 | |
| | 5 | 11.7 | |
| 100 mM n-octyl-b-D- | 0.5 | 123.5 | 6 |
| glucoside | 1 | 96.4 | |
| | 1.5 | 56.5 | |
| | 2 | 35.3 | |
| | 2.5 | 22.9 | |
| | 3 | 10.5 | |
| | 3.5 | 6.5 | |
| | 4 | 3.0 | |
| 100 mM n-octanoyl | 0.5 | 79.8 | 7 |
| sucrose | 1 | 71.7 | |
| | 1.5 | 59.9 | |
| | 2 | 44.7 | |
| | 2.5 | 31.1 | |
| | 3 | 21.1 | |
| | 3.5 | 14.6 | |
| | 4 | 9.5 | |
| 100 mM sucrose | 0.5 | 80.3 | 7 |
| monocaprate | 1 | 72.3 | |
| | 1.5 | 60.4 | |
| | 2 | 45.2 | |
| | 2.5 | 31.5 | |
| | 3 | 21.4 | |
| | 3.5 | 15.0 | |
| | 4 | 9.9 | |
| 100 mM n- | 0.5 | 93.1 | 6 |
| dodecanoyl sucrose | 1 | 77.9 | |
| | 1.5 | 57.8 | |
| | 2 | 38.1 | |
| | 2.5 | 23.9 | |
| | 3 | 11.1 | |
| | 3.5 | 5.4 | |
| | 4 | 2.6 | |
| no surfactant | 0.5 | −15.7 | 0 |
| | 1 | −9.3 | |
| | 1.5 | −6.5 | |
| | 2 | −4.7 | |
| | 2.5 | −3.5 | |
| | 3 | −2.5 | |
| | 3.5 | −1.6 | |
| | 4 | −0.9 | |

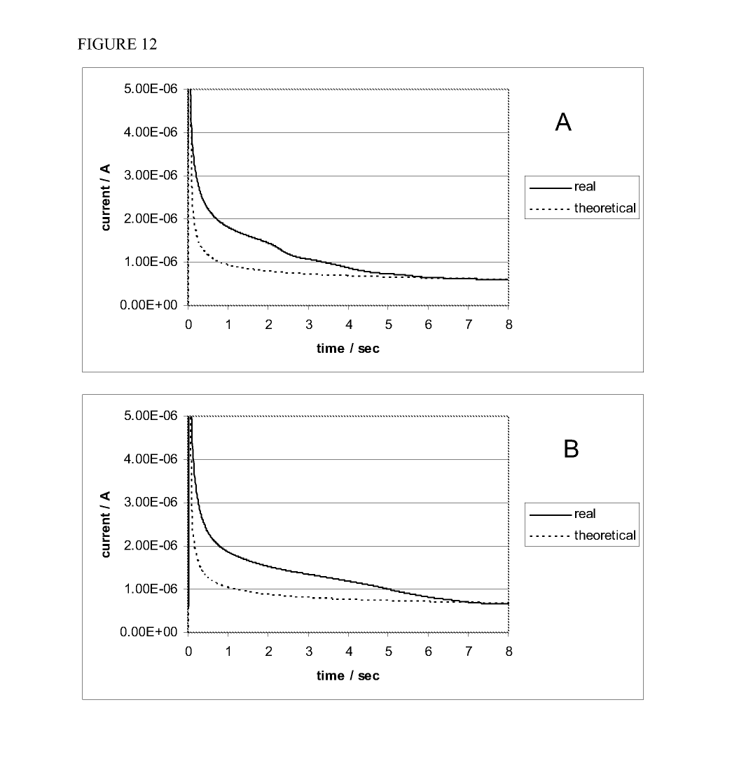

Two specific examples transient current responses to 7.5 mM NADH are shown in FIG. 12 (A is for n-heptyl-β-D-glucopyranoside surfactant and B is for Cymal-4 surfactant).

### Example 8

### Deposition Solution a (0.3 μL of Aqueous Solution was Inserted Per Electrochemical Cell)

0.1M diethanolamine (DEA) pH 8.6
1% wk myo-inositol
1% w/v ectoine

### 200 mM Anameg-7

### 3% w/v KC₁₋₈₀

### 80 mM Ru(NH₃)₆Cl₃ (RuHcx)

8.9 mM Thionicotinamide adenine dinucleotide
4.2 mg/ml Putidaredoxin Reductase
3.3 mg/ml. Lipase (Genzyme)
66 mg/ml Cholesterol Dehydrogenase, Gelatin free
x mM chemical entity

### Deposition Solution B (0.3 μL of Aqueous Solution was Inserted Per Electrochemical Cell)

### 0.1 M Tris (pH 9.0)

### 40 mM [Ru(III)(Me₃TACN)(acac)(1-MeIm)](NO₃)₂ (RuTACN)

10% w/v lactose

### 200 mM Anameg-7

8.9 mM Thionicotinamide adenine dinucleotide
4.2 mg/ml Putidaredoxin Reductase
3.3 mg/ml Lipase (Genzyme)
66 mg/ml Cholesterol Dehydrogenase, Gelatin free
x mM chemical entity

### Deposition Solution C (0.3 μL of Aqueous Solution was Inserted Per Electrochemical Cell)

### 0.1M Tris (pH 9.0)

### 40 mM KOH

### 40 mM RuAcac

10% w/v lactose

### 200 mM Anameg-7

8.9 mM thionicotinamide adenine dinucleotide
4.2 mg/ml putidaredoxin reductase
3.3 mg/ml lipase
66 mg/ml cholesterol dehydrogenase, gelatin free
x mM chemical entity

### Chemical Entity

### (iv) None

(v) 100 mM neomycin trisulphate

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Konelab clinical analyser for total cholesterol (TC) concentrations. Four samples were used:
(i) DA (3.6 mM TC)
(ii) DB (5.34 mM TC),
(iii) DC (6.79 mM TC)
(iv) DD (7.99 mM TC).

### Testing Protocol

20 μL of a plasma samples was used per electrode. On the addition of 20 μl of plasma the chronoamperometry test was initiated. The oxidation current is measured at 0.15 V at 7 time points (0, 56, 112, 168, 224, 280 and 336 seconds), with a reduction current measured at −0.45 Vat the final time point (392). The transient current was measured for 8 seconds, with a data acquisition rate of 100 Hz. Each sample was tested with at least one sensor.

### Results

The sensor responses were analyzed to obtain the current values at 8 seconds on the transient current responses, which were then used to construct calibration plots of current vs. TC concentration at each time point.

### Shoulder Analysis

Each transient current response to each sample at the final time point (336 seconds) was analyzed to determine the magnitude of the shoulder on the transient current response, by curve fitting and determining the grade of the shoulder, as described in Example 5. The grades of the shoulders are given in Table 12.

TABLE 12
Extent of shoulder for mixes of Example 8, as indicated by
grading system based on difference between experimental
current and microband theory.

| | | Grade of shoulder | | | |
|---|---|---|---|---|---|
| Mediator | Additive | DA | DB | DC | DD |
| RuHex | — | 2 | 1 | 2 | 2 |
| | 100 mM | 0 | 0 | 0 | 0 |
| | neomycin | | | | |
| Ru(TACN) | — | 7 | 9 | 10 | 14 |
| | 100 mM | 2 | 3 | 3 | 4 |
| | neomycin | | | | |
| Ru(AcAc) | — | 5 | 9 | 7 | 7 |
| | 100 mM | 4 | 4 | 4 | 5 |
| | neomycin | | | | |

### Example 9

### Deposition Solution (0.3 μL of Aqueous Solution was Inserted Per Electrochemical Cell)

### 0.1M Tris (pH 9.0)

### 40 mM KOH

### 40 mM RuAcac

10% w/v lactose

### 5% w/v CHAPS

8.9 mM thionicotinamide adenine dinucleotide
4.2 mg/ml putidaredoxin reductase
3.3 mg/ml lipase
66 mg/ml cholesterol dehydrogenase, gelatin free
x mM chemical entity

### Chemical Entity

### (vi) None

(vii) neomycin trisulphate (50, 100 or 150 mM)
(viii) spermine.4HCl (50 or 100 mM)

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac) was also used as a sample. The samples were analysed using a Konelab clinical analyser for total cholesterol (TC) concentrations. Four samples were used:
(i) CA (5.33 mM TC)
(ii) CB (6.93 mM TC)
(iii) CC (13 mM TC)
(iv) CD (4.79 mM IC).

### Testing Protocol

20 μL of a plasma samples was used per electrode. On the addition of 20 μl of plasma the chronoamperometry test was initiated. The oxidation current is measured at 0.15 V at 7 time points (0, 56, 112, 168, 224, 280 and 336 seconds), with a reduction current measured at −0.45 V at the final time point (392). The transient current was measured for 8 seconds, with a data acquisition rate of 100 Hz. Each sample was tested with at least one sensor (four electrochemical cells).

### Results

The sensor responses were analyzed to obtain the current values at 8 seconds on the transient current responses, which were then used to construct calibration plots of current vs. TC concentration at each time point.

### Shoulder Analysis

Each transient current response to each sample at the final time point (336 seconds) was also analyzed to determine the magnitude of the shoulder on the transient current response, by curve fitting and determining the grade of the shoulder, as described in Example 5. The grades of the shoulders are given in Table 13.

TABLE 13
Extent of shoulder for mixes of Example 9, as indicated by
grading system based on difference between experimental
current and microband theory.

Grade of shoulder

| Additive | CC | CD | CA | CB |
|---|---|---|---|---|
| No additive | 2 | 2 | 2 | 2 |
| 50 mM Neomycin | 2 | 2 | 2 | 0 |
| 100 mM Neomycin | 0 | 1 | 0 | 0 |
| 150 mM Neomycin | 0 | 0 | 0 | 0 |
| 50 mM Spermine | 0 | 1 | 1 | 3 |
| 100 mM Spermine | 0 | 0 | 0 | 0 |

### Example 10

### Enzyme Mix (Concentrations in the Final Mixture)

### 0.091M Tris (pH 9.0)

4.5% w/v glycine

### 27.3 mM RuAcac

4.5% w/v butyldiethylene glycol
8.1 mM thionicotinamide adenine dinucleotide
3.8 mg/ml putidaredoxin reductase
3.1 mg/ml cholesterol esterase
20 mg/ml cholesterol dehydrogenase, gelatin free
x mM chemical entity

### Chemical Entity (Concentrations in the Final Mixture)

(i) none
(ii) KCl (45.5, 227 or 455 mM)

### Scipac Samples

The LDL (Scipac) and HDL (Scipac) samples were made at approximately 10 times the required concentration (due to an approximate 1:10 dilution in the final testing mixture) using delipidated serum (Scipac). The samples were then analysed using a Space clinical analyser (Schiappanelli Biosystems Inc). Six samples were used which had the following concentrations in the final mixture:
(i) 0.45 mM HDL
(ii) 1.73 mM HDL
(iii) 3.58 mM HDL
(iv) 0.35 mM LDL
(v) 1.48 mM LDL
(vi) 2.99 mM LDL

### Wet Testing

For each sensor, 9 μL of enzyme mix was mixed with 9 μL of KCl solution. 2 μL of delipidated serum or HDL or LDL sample was added to the enzyme/KCl mix, and pippetted up and down. 9 μL of the final mix was applied to a sensor. The time from first addition of sample to the enzyme/KCl mix to initiation of the test was 30 seconds.

### Testing Protocol

On the addition of 9 μL of final mix to the sensor, the chronoamperometry test was initiated. The oxidation current is measured at 0.15 V at 7 time points (0, 32, 64, 96, 128, 160 and 192 seconds), with a reduction current measured at −0.45 V at the final time point (224). The transient current was measured for 4 seconds, with a data acquisition rate of 200 Hz. Each sample was tested with at least one sensor (four electrochemical wells).

### Results

The sensor responses were analyzed to obtain the current values at 4 seconds on the transient current responses, which were then used to construct calibration plots of current vs. HDL or LDL concentration at each time point.

### Shoulder Analysis

Each transient current response to each sample at the final time point (192 seconds) was analyzed to determine the magnitude of the shoulder on the transient current response, as described in Example 5. The grades of the shoulders are given in Table 14.

TABLE 14
Extent of shoulder for mixes of Example 10, as indicated by
grading system based on difference between experimental
current and microband theory.

| | Grade of shoulder | | | |
|---|---|---|---|---|
| Sample | 0 mM KCl | 45 mM KCl | 227 mM KCl | 455 mM KCl |
| 0.45 mM HDL | 2 | 2 | 0 | 0 |
| 1.73 mM HDL | 3 | 2 | 0 | 0 |
| 3.58 mM HDL | 4 | 2 | 1 | 0 |
| 0.35 mM LDL | 4 | 3 | 1 | 0 |
| 1.48 mM LDL | 4 | 2 | 0 | 0 |
| 2.99 mM LDL | 5 | 3 | 1 | 0 |

### Example 11

### Deposition Solution (0.4 μL of Aqueous Solution was Inserted Per Electrochemical Cell)

### 0.1M Tris (pH 9.0)

### 30 mM KOH

### 30 mM RuAcac

10% w/v lactose

### 200 mM HEGA-9

8.9 mM thionicotinamide adenine dinucleotide
4.2 mg/ml putidaredoxin reductase
3.5 mg/ml lipase
22 mg/ml cholesterol dehydrogenase, gelatin free
x mM chemical entity

### Chemical Entity

(i) None
(ii) LiCl (0.25, 0.5 or 0.75 M)
(iii) NaCl (0.25 or 0.5 M)
(iv) CaCl₂ (0.125 or 0.25 M)
(v) MgCl₂ (0.125 or 0.25 M)
(vi) Co(NH₃)₆Cl₃ (30 or 60 mM)

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Space clinical analyser for HDL concentrations. Five samples were used:

### (i) EA (1.13 mM HDL)

### (ii) EB (2.56 mM HDL)

(iii) EC (2.05 mM HDL)

### (iv) ED (1.87 mM HDL)

### (v) EE (1.51 mM HDL)

(Note: additional samples were also tested for HDL and LDL response and were used to construct calibration plot).

### Testing Protocol

12 μL of a plasma sample was used per electrode. On the addition of 12 μl of plasma the chronoamperometry test was initiated. The oxidation current was measured at 0.15 Vat 8 time points (0, 59, 118, 177, 236, 295, 354 and 413 seconds), with a reduction current measured at −0.45 V at the final time point (472). The transient current was measured for 8 seconds, with a data acquisition rate of 100 Hz. Each sample was tested with at least one sensor (four electrochemical cells).

### Results

The sensor responses were analyzed to obtain the current values at 8 seconds on the transient current responses, which were then used to construct calibration plots of current vs. HDL concentration at each time point.

### Shoulder Analysis

The transient current responses to each sample (EA, EB, EC, ED and EE) at the final time point (413 seconds) were analyzed to determine the magnitude of the shoulder on the transient current response, as described to Example 5. The grades of the shoulders are given in Table 15.

TABLE 15
Extent of shoulder for mixes of Example 11, as indicated
by grading system based on difference between experimental
current and microband theory.

| | Grade of shoulder | | | | |
|---|---|---|---|---|---|
| Additive | EA | EB | EC | ED | EE |
| No additive | 10 | 12 | 10 | 10 | 11 |
| 250 mM LiCl | 6 | 8 | 8 | 7 | 8 |
| 500 mM LiCl | 5 | 6 | 6 | 5 | 5 |
| 750 mM LiCl | 4 | 3 | 4 | 3 | 4 |
| 250 mM NaCl | 5 | 7 | 6 | 7 | 7 |
| 500 mM NaCl | 4 | 6 | 6 | 6 | 6 |
| 125 mM CaCl₂ | 6 | 8 | 7 | 7 | 8 |
| 250 mM CaCl₂ | 4 | 5 | 4 | 5 | 5 |
| 125 mM MgCl₂ | 7 | 8 | 8 | 11 | 7 |
| 250 mM MgCl₂ | 5 | 6 | 6 | 6 | 6 |
| 30 mM Co(NH₃)₆Cl₃ | 8 | 9 | 9 | 10 | 6 |
| 60 mM Co(NH₃)₆Cl₃ | 5 | 7 | 6 | 5 | 6 |

### Example 12

### Deposition Solution (0.4 μL of Aqueous Solution was Inserted Per Electrochemical Cell)

### 0.1M Tris (pH 9.0)

### 30 mM KOH

### 30 mM RuAcac

10% w/v lactose

### 5% w/v HEGA-8

8.9 mM thionicotinamide adenine dinucleotide
4.2 mg/ml putidaredoxin reductase
3.3 mg/ml lipase
22 mg/ml cholesterol dehydrogenase, gelatin free
x mM chemical entity

### Chemical Entity

(i) none
(ii) 100 mM neomycin sulphate

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Space clinical analyser for HDL concentrations. Five samples were used:
(i) FA (1.93 mM HDL)
(ii) FB (1.49 mM HDL)
(iii) FC (1.36 mM HDL)
(iv) FD (1.64 mM HDL)
(v) FE (1.29 mM HDL)
   (Other samples were also tested for HDL and LDL response and were used to construct calibration plots).

### Testing Protocol

12 μL of a plasma sample was used per electrode. On the addition of 12 μl of plasma the chronoamperometry test was initiated. The oxidation current is measured at 0.15 V at 13 time points (0, 32, 64, 96, 128, 160, 192, 224, 256, 288, 320, 352 and 384 seconds), with a reduction current measured at −0.45 V at the final time point (416 seconds). The transient current was measured for 4 seconds, with a data acquisition rate of 200 Hz. Each sample was tested with at least one sensor (four electrochemical cells).

### Results

The sensor responses were analyzed to obtain the current values at 4 seconds on the transient current responses, which were then used to construct calibration plots of current vs. HDL concentration at each time point.

### Shoulder Analysis

Each transient current responses to some samples (FA, FB, FC, FD and FE) at the final time point (413 seconds) were analyzed to determine the magnitude of the shoulder on the transient current response, as described in Example 5. The grades of the shoulders are given in Table 16.

TABLE 16
Extent of shoulder for mixes of Example 12, as indicated
by grading system based on difference between experimental
current and microband theory.

| | Grade of shoulder | | | | |
|---|---|---|---|---|---|
| Additive | FA | FB | FC | FD | FE |
| No additive | >8 | >8 | >8 | >8 | >8 |
| 100 mM Neomycin | 6 | 5 | 5 | 5 | 5 |

### Example 13

### Deposition Solution (0.3 μL of Aqueous Solution was Inserted Per Electrochemical Cell)

### 0.1M DEA (pH 8.6)

1% w/v myo-inositol
1% w/v ectoine

### 200 mM Anameg-7

### 3% w/v KCl

8.9 mM Thionicotinamide adenine dinucleotide, potassium salt
4.2 mg/ml Putidaredoxin Reductase
3.3 mg/ml Cholesterol esterase (Toyobo)
66 mg/ml Cholesterol Dehydrogenase, Gelatin free

### X mM Ru(NH₃)₆Cl₃

### Mediator and Chemical Entity

(1) 25 mM Ru(NH₃)₆Cl₃
(ii) 50 mM Ru(NH₃)₆Cl₃
(iii) 100 mM Ru(NH₃)₆Cl₃
(iv) 150 mM Ru(NH₃)₆Cl₃

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using: a Konelab clinical analyser for total cholesterol (TC) concentrations. Four samples were used:
(i) HA (3.58 mM TC)
(ii) HB (5.38 mM TC)
(iii) HC (6.45 mM TC)
(iv) HD (8.25 mM TC).

### Testing Protocol

20 μL of a plasma sample was used per electrode. On the addition of 20 μL of plasma the chronoamperometry test was initiated. The oxidation current is measured at 0.15 V at 7 time points (0, 56, 112, 168, 224, 280 and 336 seconds), with a reduction current measured at −0.45 V at the final time point (392 seconds). The transient current was measured for 8 seconds, with a data acquisition rate of 100 Hz. Each sample was tested with at least one sensor (four electrochemical cells).

### Results

The sensor responses were analyzed to obtain the current values at 8 seconds on the transient current responses, which were then used to construct calibration plots of current vs. total cholesterol concentration at each time point.

### Shoulder Analysis

Each transient current response to samples (HA, HB, HC and HD) at the final time point (336 seconds) was analyzed to determine the magnitude of the shoulder on the transient current response, by curve fitting to determine the grade of the shoulder, as described in Method 2 of Example 5. The grades of the shoulders are given in Table 17.

TABLE 17
Extent of shoulder for mixes of Example 13, as indicated by
grading system based on difference between experimental
current and microband theory.

Grade of shoulder

| | HA | HB | HC | HD |
|---|---|---|---|---|
| 25 mM Ru(NH₃)₆Cl₃ | 2 | 2 | 3 | 3 |
| 50 mM Ru(NH₃)₆Cl₃ | 2 | 2 | 3 | 3 |
| 100 mM Ru(NH₃)₆Cl₃ | 1 | 1 | 2 | 2 |
| 150 mM Ru(NH₃)₆Cl₃ | 1 | 1 | 1 | 2 |

### Example 14

### Deposition Solution (0.4 μL of Aqueous Solution was Inserted Per Electrochemical Cell)

### 0.1M HEPBS (pH 9.0)

### 30 mM [Ru(III)(Me₃TACN)(acac)(1-MeIm)]NO₃)

10% w/v lactose

### 1% w/v Anameg-7

17.6 mM Thionicotinamide adenine dinucleotide
6.7 mg/ml Diaphorase
5 mg/ml Lipase (Genzyme)
45 mg/ml Glycerol Dehydrogenase
X mM Chemical entity

### Chemical Entity

(i) None
(ii) 2.5% KCl
(iii) 5% KCl

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Konelab clinical analyser for triglyceride (TRG) concentrations. Three samples were used:
(i) GA (0.62 mM TRG)
(ii) GB (2.0 mM TRG)
(iii) GC (3.03 mM TRG).

### Testing Protocol

12 μL of a plasma sample was used per electrode. On the addition of 12 μL of plasma the chronoamperometry test was initiated. The oxidation current is measured at 0.15 V at 13 time points (8, 42, 76, 110, 144, 178, 212, 246, 280, 314, 348, 382 and 416 seconds), with a reduction current measured at −0.45 V at the final time point (450 seconds). The transient current was measured for 4 seconds, with a data acquisition rate of 200 Hz. Each sample was tested with at least one sensor (four electrochemical cells).

### Results

The sensor responses were analyzed to obtain the current values at 4 seconds on the transient current responses, which were then used to construct calibration plots of current vs. TRG concentration at each time point.

### Shoulder Analysis

Transient current responses to some samples (GA, GB and GC) at the final time point (416 seconds) were also analyzed to determine the magnitude of the shoulder on the transient, current response, by curve fitting to determine the grade of the shoulder, as described in Method 2 of Example 5. The grades of the shoulders are given in Table 18.

TABLE 18
Extent of shoulder for mixes of Example 14, as indicated by
grading system based on difference between experimental
current and microband theory.

| | Grade of shoulder | | |
|---|---|---|---|
| | GA | GB | GC |
| 0% KCl | 1 | 1 | 0 |
| 2.5% KCl | 0 | 0 | 0 |
| 5% KCl | 0 | 0 | 0 |

### Example 15

### Deposition Solution (0.4 μL of Aqueous Solution was Inserted Per Electrochemical Cell)

### 0.1M HEPBS (pH 9.0)

### 30 mM RuAcac

### 30 mM KOH

10% w/v lactose
150 mM n-nonyl-β-D-glucopyranoside (NOP)
17.6 mM Thionicotinamide adenine dinucleotide
6.7 mg/ml Diaphorase
5 mg/ml Lipase (Genzyme)
45 mg/ml Glycerol Dehydrogenase

The dispensed sensor sheets were then placed into a LS40 freeze drier (Severn Science) for freeze drying.

### Plasma Samples

Plasma samples were defrosted for 30 minutes before being centrifuged for 5 minutes at 2900 RCF (Labnet 1618). Delipidated serum (Scipac, S139) was also used as a sample. The samples were analysed using a Space clinical analyser for triglyceride (TRO) concentrations. Four samples were used:

### (i) JA (1.13 mM TRG)

### (ii) JB (3.96 mM TRG)

(iii) JC (1.83 mM TRG)

### (iv) JD (3.26 mM TRG).

### Testing Protocol

12 μL of a plasma sample was used per electrode. On the addition of 12 μl of plasma the chronoamperometry test was initiated using a multiplexer (MX452, Sternhagen design) attached to an Autolab (PGSTAT 12). The oxidation current was measured at 0.15 V at 13 time points (8, 42, 76, 110, 144, 178, 212, 246, 280, 314, 348, 382 and 416 seconds), with a reduction current measured at −0.45 V at the final time point (450 seconds). The transient current was measured for 4 seconds, with a data acquisition rate, of 200 Hz. Each sample was tested with at least one sensor (four electrochemical wells).

### Results

The sensor responses were analyzed to obtain the current values at 4 seconds on the transient current responses, which were then used to construct calibration plots of current vs. TRG concentration at each time point.

### Shoulder Analysis

Transient current responses to each sample at the final time point (4.16 seconds) were analyzed to determine the magnitude of the shoulder on the transient current response, by curve fitting to determine the grade of the shoulder, as described in Example 5. The grades of the shoulders are given in Table 19.

TABLE 19
Extent of shoulder for mix of Example 15, as indicated by
grading system based on difference between experimental
current and microband theory.
Grade of shoulder

| JA | JB | JC | JD |
|---|---|---|---|
| 4 | 4 | 3 | 4 |

The invention has been described with reference to various embodiments and examples. However, it is to be understood that the invention is in no way limited to these embodiments and examples.

The features disclosed in the above description, the claims and the drawings may be important both individually and in any combination with one another for implementing the invention in its various embodiments.

It is noted that terms like “preferably”, “commonly”, and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the present invention in detail and by reference to specific embodiments thereof, it will be apparent that modification and variations are possible without departing from the scope of the present invention defined in the appended claims. More specifically, although some aspects of the present invention are identified herein as preferred or particularly advantageous, it is contemplated that the present invention is not necessarily limited to these aspects of the present invention.

What is claimed is:

1. A measurement cell comprising at least two electrodes, a redox agent, and at least one chemical entity, the cell being configured for use in an electrochemical method involving measurement of a current between the at least two electrodes when the cell and the redox agent contact a liquid sample and a potential is applied across the electrodes, the potential generating a peak current that subsequently decays, wherein:
(a) each chemical entity comprises one of an aminoglycoside, an organic polyamine, and a substance capable of raising the ionic strength of the sample, and is substantially redox-inactive; and
(b) each chemical entity being provided in the measurement cell in sufficient amounts so as to be suitable for increasing the rate of decay of current from said peak current thereby at least reducing the occurrence of signal distortion of the current.

2. The measurement cell according to claim 1, wherein said chemical entity comprises an aminoglycoside selected from streptomycin, apramycin, paromomycin, amikacin, neomycin and gentamycin.

3. The measurement cell according to claim 1, wherein said chemical entity comprises an organic polyamine selected from spermidine and spermine.

4. The measurement cell according to claim 1, wherein said chemical entity comprises a substance capable of raising the ionic strength of the sample, said substance comprising an inorganic salt selected from the group consisting of LiCl, NaCl, MgCl₂, CaCl₂, Cr(NH₃)₆Cl₃ and Co(NH₃)₆Cl₃.

5. The measurement cell according to claim 1, wherein the redox agent and at least one chemical entity comprise a reagent mixture, wherein the redox agent is present in the reagent mixture in an amount from about 0.1 to about 400 mM, each chemical entity comprising aminoglycoside or organic polyamine is present in the reagent mixture in an amount from about 10 to about 500 mM, and each chemical entity comprising a substance capable of raising the ionic strength of the sample comprises an inorganic salt present in the reagent mixture in an amount from about 0.1 to about 5 M.

6. The measurement cell according to claim 1, wherein said signal distortion comprises a contribution to the current resulting from pseudocapacitance of the electrodes.

7. The measurement cell according to claim 1, wherein the at least one chemical entity is located in the cell such that said sample contacts the at least one chemical entity prior to the application of said potential during the electrochemical method.

8. The measurement cell according to claim 1, the cell further comprising at least one of (i) at least one enzyme, (ii) a surfactant, (iii) a coenzyme, (iv) a reductase, (v) a cholesterol ester hydrolysing agent, and (vi) a triglyceride hydrolysing reagent.

9. The measurement cell according to claim 1, wherein the redox agent is configured for the detection of at least one of cholesterol and triglyceride present in said sample.

10. The measurement cell according to claim 1, wherein at least one of the at least two electrodes is a microelectrode comprising a microband electrode.

11. An electrochemical method for detection of cholesterol or triglyceride present in a sample, comprising:
(a) providing a measurement cell comprising at least two electrodes, a redox agent and at least one chemical entity;
(b) contacting said sample in the measurement cell with the redox agent and the at least one chemical entity, wherein each chemical entity is substantially redox-inactive and comprises one of an aminoglycoside, an organic polyamine, and a substance capable of raising the ionic strength of the sample;
(c) applying a potential across the electrodes and thereby generating a current which comprises a peak current that subsequently decays over time, the rate of decay from the peak current being increased by the presence in the measurement cell of the at least one chemical entity relative to a measurement cell not having at least one said chemical entity; and
(d) measuring a current between the at least two electrodes after occurrence of the peak current.

12. The electrochemical method according to claim 11, wherein the redox agent comprises at least enzyme and at least one of a surfactant, a coenzyme, a reductase, a cholesterol ester hydrolysing agent and a triglyceride hydrolysing reagent.

13. The electrochemical method according to claim 12, wherein said at least one enzyme comprises one of cholesterol oxidase and cholesterol dehydrogenase.

14. The electrochemical method according to claim 12, wherein said at least one enzyme comprises glycerol kinase in combination with one of glycerol dehydrogenase and glycerol phosphate oxidase.

15. The electrochemical method according to claim 11, wherein at least one of the at least two electrodes comprises a microelectrode.

16. A reagent mixture for use in an electrochemical method, comprising:
(a) a redox agent;
(b) one or more chemical entities, wherein each chemical entity is substantially redox-inactive and comprises one of an aminoglycoside, an organic polyamine, and a substance capable of raising the ionic strength of the sample; and
(c) one or more of (i) glycerol phosphate oxidase in combination with glycerol kinase, (ii) cholesterol oxidase, (iii) cholesterol dehydrogenase, and (iv) glycerol dehydrogenase.

17. The reagent mixture according to claim 16, wherein the reagent mixture further comprises at least one of a surfactant, a coenzyme, a cholesterol ester hydrolysing reagent, a triglyceride hydrolysing reagent, and a reductase.

18. A kit for the determination of the amount of cholesterol or triglyceride in a sample, the kit comprising:
an electrochemical cell comprising at least two electrodes;
the reagent mixture as defined in claim 16;
a voltage source arranged to selectively apply a voltage across the cell; and
a measurement circuit arranged to obtain measurements of an electrochemical parameter on the cell.

19. A kit according to claim 18, wherein one of said at least two electrodes comprises a microelectrode.
